(19) United States
(12) Patent Application Publication
(10) Pub. No.: US 2025/0210302 A1
(43) Pub. Date: Jun. 26, 2025

(54) METHOD FOR VOLTAGE CONTRAST IMAGING WITH A CORPUSCULAR MULTI-BEAM MICROSCOPE, CORPUSCULAR MULTI-BEAM MICROSCOPE FOR VOLTAGE CONTRAST IMAGING AND SEMICONDUCTOR STRUCTURES FOR VOLTAGE CONTRAST IMAGING WITH A CORPUSCULAR MULTI-BEAM MICROSCOPE

(71) Applicant: Carl Zeiss MultiSEM GmbH, Oberkochen (DE)

(72) Inventors: Gregor Frank Dellemann, Aalen (DE); Stefan Schubert, Oberkochen (DE); Dirk Zeidler, Oberkochen (DE)

(21) Appl. No.: 18/974,282

(22) Filed: Dec. 9, 2024

Related U.S. Application Data
(63) Continuation of application No. 17/731,726, filed on Apr. 28, 2022, now abandoned.
Application No. 17/731,726 is a continuation of application No. PCT/EP2020/080090, filed on Oct. 27, 2020.

(30) Foreign Application Priority Data
Nov. 27, 2019 (DE) 10 2019 218 315.8

(51) Int. Cl. H01J 37/28; H01J 37/02

(52) U.S. Cl. CPC H01J 37/28; H01J 37/026; H01J 2237/0048; H01J 2237/0435

(57) ABSTRACT

A method for voltage contrast imaging, for example on a semiconductor sample, uses a corpuscular multi-beam microscope with a multiplicity of individual corpuscular beams in a grid arrangement. The method includes sweeping the multiplicity of individual corpuscular beams over a sample having at least one electrically chargeable structure, and charging the sample with a first quantity of first corpuscular beams of the corpuscular multi-beam microscope. The method also includes determining a voltage contrast at the at least one electrically chargeable structure of the sample with a second quantity of second corpuscular beams of the corpuscular multi-beam microscope.

### CROSS-REFERENCE TO RELATED APPLICATIONS

The present application is a continuation of, and claims benefit under 35 USC 120 to, U.S. application Ser. No. 17/731,726, filed Apr. 28, 2022, which is a continuation of, and claims benefit under 35 USC 120 to, international application PCT/EP2020/080090, filed Oct. 27, 2020, which claims benefit under 35 USC 119 of German Application No. 10 2019 218 315.8, filed Nov. 27, 2019. The entire disclosure of these applications are incorporated by reference herein.

### FIELD

The disclosure relates to a method for detecting defects, for example, in semiconductor structures by voltage contrast imaging with a corpuscular multi-beam microscope. The disclosure furthermore relates to a corpuscular multi-beam microscope suitable for voltage contrast imaging, for example on semiconductor structures. The disclosure furthermore relates to semiconductor structures for voltage contrast imaging with a corpuscular multi-beam microscope.

### BACKGROUND

Corpuscular beam microscopes having a multiplicity of corpuscular beams are known. U.S. Pat. No. 9,673,024 B2 discloses one such device using electrons as corpuscular particles, wherein an aperture mask is disposed downstream of an electron beam source, and produces a multiplicity of corpuscular beams in a corpuscular beam grid arrangement. The multiplicity of corpuscular beams pass through a corpuscular beam optical unit including a beam splitter and each corpuscular beam is focused in parallel onto a sample.

The secondary electrons reflected back or emitted there are captured in parallel by the corpuscular beam optical unit and directed via the beam splitter onto a detector unit, which can resolve each individual beam of the corpuscular beam grid arrangement. Regular corpuscular beam grid arrangements of approximately 10×10 beams arranged in a regular cartesian or hexagonal grid are customary, wherein individual corpuscular beams are at a distance of approximately 10 μm from one another. In order to detect a complete image field, the corpuscular beams in the corpuscular beam grid arrangement are guided synchronously over the sample in a zigzag-like movement, for example, with a scanning unit and the temporal sequence of the detector signals is converted into a spatial arrangement for ascertaining an image segment. Alternatively, corpuscular multi-beam microscopes having a parallel arrangement of a plurality of corpuscular beam microscopes with individual beams are known. Corpuscular particles for corpuscular beam microscopes can be electrons or charged particles, such as metal ions, for example gallium ions, or ions of gases, for example helium.

Voltage contrast images are usually generated by a structure that can take up charge being charged and then observed by observation using a corpuscular beam microscope. In this case, a corpuscular beam is scanned or swept in scanning fashion over a sample to be examined, and reflected corpuscular particles or secondary emissions such as secondary electrons or photons are detected.

So-called passive voltage contrast imaging involves detecting stored charge states in structures. K. Crosby et al., “Towards Fast and Direct Memory Read-out by Multi-beam Scanning Electron Microscopy and Deep Learning Image Classification” (Microscopy and Microanalysis 25.S2 (2019), pp 192-193) describe a method of passive voltage contrast imaging using a corpuscular beam microscope with a multiplicity of corpuscular beams, an MSEM. In this case, the imaging is effected on memory cells of an EEPROM in which data are stored in the form of electrical charges. The stored data can thus be deduced by way of the voltage contrast of the imaging of the memory cells. In this case, the imaging is effected with a very low dose of the corpuscular beams, in order not to influence the charges of the memory cells.

Voltage contrast imaging is one known method for detecting defects in semiconductor structures. Such defects can arise as a result of process fluctuations during the production of integrated semiconductors, or as a result of not fully matured processes during process development. Voltage contrast images are therefore used in process development and process monitoring for the production of integrated semiconductor circuits.

In this case, corpuscular beams generally contribute to a charging of the sample to be examined. Since a change in the imaging properties of the sample as a result of charging is generally undesired, however, low corpuscular currents are employed during imaging. However, a high resolution generally involves low corpuscular currents, and the charging effects are small at high resolution. Voltage contrast imaging with high corpuscular currents is possible, but can greatly limit the imaging and for example the resolution of the imaging with the corpuscular beam microscope.

The resolution of a corpuscular beam microscope is usually dominated by the lens aberrations. The diameter d_{E} of an electron beam focal point, for example, is composed of the diameter of the image of the electron beam source d_{source}, the diffraction error d_{diffraction} and the lens aberrations d_{aberrations} of the electron beam optical unit:

$${d}_{E} = \sqrt{{d}_{diffraction}^{2} + {d}_{s o u r c e}^{2} + {d}_{a b e rration}^{2}}$$

The diffraction error d_{diffraction} generally decreases as the aperture angle α increases. The lens aberration d_{aberration} is composed of many individual aberrations such as astigmatism, spherical aberration, coma and chromatic aberration or aberration as a result of dispersion over the energy bandwidth ΔE of the corpuscular beam. Lens aberrations generally increase greatly as the aperture angle α increases, and are typically minimized by corresponding design and correction of the corpuscular beam optical unit up to a maximum aperture angle αₘₐₓ. The aperture angle αₘₐₓ of the imaging of the corpuscular particles is typically set such that diffraction error d_{diffraction} and lens aberrations d_{aberration} together become minimal.

A small diameter d_{E} of the focal point of the corpuscular beam is often used for the desired high resolution in the range of a few nm. For this purpose, the corpuscular beam source is imaged in a reduced manner by way of an imaging scale M<1, such that the reduced source image size d_{source} can be disregarded. A small imaging scale M can result in an increase in the aperture angle αₘₐₓ or in the aperture of the individual corpuscular beams and thus in an increase in the lens aberrations. Therefore, in general, a high-resolution imaging is possible only with very small aperture angles at the corpuscular beam source and low radiant intensities result for high-resolution imaging.

For charging a sample for voltage contrast imaging, therefore, a large magnification is often chosen, for example, as a result of which the source image is magnified and the resolution is reduced. This can result in large aperture angles at the electron beam source and more charge is taken up and directed into the sample. On the other hand, voltage contrast imaging with corpuscular beam microscopes with high resolution and simultaneous charging has generally been possible only with limitations hitherto.

U.S. Pat. No. 7,528,614 B2 proposes an alternative method for charging the sample. For this purpose, U.S. Pat. No. 7,528,614 B2 proposes separate precharge electron beam guns (so-called “flood guns”) that charge the sample. It is mentioned that a plurality of such precharge electron beam guns can also be used. In the second step, the voltage contrast imaging is effected with a high-resolution corpuscular beam microscope. It is mentioned that the corpuscular beam microscope can be a multi-beam microscope. The separate precharge electron beam guns allow only a global, spatially unresolved charging of the sample and involve a large working distance between sample and high-resolution corpuscular beam microscope. In general, it can be desirable for the region of the sample which is to be charged is able to be reached by the flood gun. That can be difficult in the case of electron microscopes for high resolution with a small working distance since the flood gun then has to introduce radiation from the side at a very shallow angle. This arrangement can be undesirable for example for corpuscular multi-beam microscopes having the larger diameter of the last lens module for the corpuscular beams.

High-resolution corpuscular beam microscopes in addition often operate in the so-called immersion mode, an electric or magnetic field being present between sample and corpuscular beam microscope. This immersion field furthermore can hamper sample charging with separate precharge electron beam guns. U.S. Pat. No. 9,165,742 B1 discloses further examples of separate precharge electron beam guns, which can additionally involve time-consuming switching and realignment of the optical unit of the corpuscular beam microscope.

The minimum lateral structure sizes (CD) of semiconductor structures are currently approximately 5 nm, and it should be expected that the minimum structure sizes will continue to shrink and in a few years will be less than 3 nm, such as less than 2 nm or even less. In general, a resolution of this order of magnitude is possible only with low corpuscular currents. In order both to introduce a sufficient quantity of charge into the semiconductor structure to be measured and to ensure a sufficient resolution, it is known to use the relatively time-consuming two-stage process for voltage contrast imaging. In the first stage, the sample to be examined is charged in the so-called precharge mode, the corpuscular beam microscope being operated with a high corpuscular current. In the second step, the corpuscular beam microscope is then switched to the high-resolution imaging mode with a low corpuscular current, and the voltage contrast image is captured.

U.S. Pat. No. 5,959,459 A proposes the method of voltage contrast imaging with the two-stage process with different magnifications. The sample is charged at a first, low magnification and a suspected defect is localized at a second, higher magnification. This process involves a spatial movement of the sample; for example, a change in distance between sample and corpuscular beam optical unit is involved for switching to for example high resolution. In general, this method is thus very time-consuming. Therefore, in general, this method cannot be used for present desired resolution and throughput.

US 2017/0287675 A1 proposes this two-stage process for voltage contrast imaging, wherein for the first step of the precharge mode a control unit modifies one or more components of the corpuscular beam microscope.

U.S. Pat. No. 7,217,579 B2 proposes the two-stage process for voltage contrast imaging for monitoring a fabrication process, wherein specific test structures or PCMs are applied or introduced on a wafer. A small region of these extensive PCMs, a so-called pad or platelet, is brought into the small field of an SEM. In a first step, the SEM is operated in the precharge mode until the test structures are sufficiently charged. In a second step, the SEM is switched to the imaging mode, and a voltage contrast image is captured. Besides the issues already mentioned, the small field of an SEM furthermore can limit the arrangement and the design of the extensive test structures or PCMs.

Generally, the two-stage process for voltage contrast imaging has various undesirable aspects and limitations. Firstly, the possibility of switching can involve taking this specially into account in the design of the corpuscular beam microscope. Secondly, the two-stage process for voltage contrast imaging can be time-consuming. By way of example, recalibration and determination of the image position of the corpuscular beam microscope may be involved when the corpuscular beam microscope is switched from the high-current to the low-current mode. Hysteresis effects in magnetic components could lead to poorly reproducible alignment settings. Furthermore, changes in charging states could arise in the apparatus as a result of the switching, which changes then lead to drifts in the event of switching.

Furthermore, during the two-stage process, for example with switching of the corpuscular beam microscope, a time interval can arise between the charging and the voltage contrast imaging, as a result of which the two-stage process with switching is usable only to a limited extent. As a result of the natural loss of charge in semiconductor samples, for example as a result of leakage or tunnelling currents, charges and thus voltages can decrease over time, such that for example large voltages from small capacitances from small semiconductor structures can decrease rapidly and can no longer be measured reliably.

WO 2019/115391 A1 proposes a method of voltage contrast imaging for ascertaining alignment errors. The document proposes providing in each case conductive test structures in a manner stacked one above another in different adjacent layers of the integrated semiconductor. As a result of process errors during the production of a layer, the test structures in the layer may have incorrect lateral arrangements and, consequently, a test structure may no longer overlap a test structure in an adjacent layer. The interrupted connection can influence the capacitance of the structure and thus the voltage contrast imaging with an electron microscope.

An interruption between two test structures occurs if the respective test structures in the adjacent layers no longer overlap. Here WO 2019/115391 A1 proposes the use of the large alignment marks present for optical alignment. The proposed method is therefore generally suitable only for very coarse alignment. Furthermore, the application does not explain a solution for the charging of the large capacitances of the alignment marks with the low currents of a corpuscular beam microscope with high resolution.

Carrying out the voltage contrast imaging on semiconductor structures of different sizes or having different capacitances can raise issues. In the case of charging by way of “flood guns” or by way of corpuscular beam microscopes in the precharge mode, with a sufficient quantity of charge and/or irradiation time it is possible to ensure that even very large structures having a large capacitance are sufficiently charged. With corpuscular beam microscopes with high resolution and low corpuscular currents, it is generally the case that only very small quantities of charge can be introduced into a sample and hence only very small semiconductor structures having a small capacitance can be sufficiently charged in a limited time. By contrast, charging larger, ramified structures can involve a very long irradiation time in the high-resolution mode.

### SUMMARY

The present disclosure seeks to provide a method in order, for example in a semiconductor sample, to charge structures and to carry out voltage contrast imaging with a high-resolution corpuscular multi-beam microscope.

The present disclosure also seeks to enable high-resolution voltage contrast imaging with precharging without switching of a corpuscular multi-beam microscope.

The present disclosure further seeks to provide a method, for example in a semiconductor sample, to charge structures simultaneously in a targeted manner and locally and to carry out high-resolution voltage contrast imaging with a high-resolution corpuscular multi-beam microscope.

In addition, the present disclosure seeks to provide a method, for example in a semiconductor sample, to charge structures having different capacitances simultaneously in a targeted manner and locally and to carry out high-resolution voltage contrast imaging on semiconductor structures having different capacitances with a high-resolution corpuscular multi-beam microscope.

Moreover, the present disclosure seeks to provide a high-resolution corpuscular multi-beam microscope for voltage contrast imaging on specific structures, for example semiconductor structures.

Furthermore, the present disclosure seeks to provide semiconductor structures for defect detection with voltage contrast imaging with a corpuscular multi-beam microscope.

The present disclosure also seeks to provide test structures for which small lateral inaccuracies of, for example, approximately 1 nm in the layer construction of a semiconductor structure can lead to a voltage contrast change and can be charged with a corpuscular beam grid arrangement and are accessible to high-resolution voltage contrast imaging.

The present disclosure further seeks to provide a method, a corpuscular multi-beam microscope and a semiconductor structure for ascertaining deviations or defects in semiconductor structures for the process development of the fabrication processes of semiconductor structures.

In addition, the present disclosure seeks to provide a method, a corpuscular multi-beam microscope and a semiconductor structure for ascertaining deviations or defects in semiconductor structures.

The disclosure provides a method in order, in a sample, for example a semiconductor sample, to charge electrically chargeable structures, for example semiconductor structures, and to carry out voltage contrast imaging with a high-resolution corpuscular multi-beam microscope with low corpuscular currents of selected individual corpuscular beams of the corpuscular beam grid arrangement. In this case, an additive total current formed from the sum of the selected corpuscular beams each having a low corpuscular current brings about a charge and hence a voltage difference in the electrically chargeable structure or semiconductor structure. According to the disclosure, the corpuscular beam microscope for charging and determining the voltage contrast remains unchanged, and the individual corpuscular currents of the first and second corpuscular beams remain largely the same.

One embodiment of the disclosure relates to a method for voltage contrast imaging on a sample with a corpuscular multi-beam microscope with a multiplicity of individual corpuscular beams in a grid arrangement, including sweeping over a sample having at least one electrically chargeable structure in a scanning manner using the multiplicity of individual corpuscular beams, charging the sample with a first quantity of first corpuscular beams of the corpuscular multi-beam microscope and determining a voltage contrast at the at least one electrically chargeable structure of the sample with a second quantity of second corpuscular beams of the corpuscular multi-beam microscope. In one embodiment, at least one first corpuscular beam of the first quantity of first corpuscular beams is not contained in the second quantity of the second corpuscular beams. In one embodiment, at least one second corpuscular beam of the second quantity of second corpuscular beams is not contained in the first quantity of the first corpuscular beams. In one embodiment, the first quantity of first corpuscular beams includes at least one first corpuscular beam. In one embodiment, the second quantity of second corpuscular beams includes at least one second corpuscular beam. In one embodiment, the first quantity of first corpuscular beams includes at least two first corpuscular beams, wherein the at least two first corpuscular beams each have a first corpuscular current, and an additive total current formed from the sum of the at least two first corpuscular currents generates an accumulated electrical charging and thus a voltage difference in the structure. The corpuscular current of a second corpuscular beam for determining the voltage contrast at the sample is less than the additive total current of the first quantity of first corpuscular beams, such that the accumulated electrical charging of the chargeable structure remains substantially unchanged as a result of the corpuscular current of the second corpuscular beam. In one embodiment of the disclosure, one corpuscular beam of the first quantity of first corpuscular beams is identical with at least one corpuscular beam of the second quantity of second corpuscular beams.

One embodiment of the disclosure provides for making available a method in order, in a sample, to precharge electrically chargeable structures and then to carry out voltage contrast imaging using a corpuscular multi-beam microscope. In this case, the precharging is effected in the high-resolution corpuscular multi-beam microscope. The additive total current formed from the sum of the plurality of corpuscular beams each having a low corpuscular current brings about a charge and hence voltage difference in the electrically chargeable structure, which can be detected according to the disclosure in the second step of the voltage contrast imaging using the high-resolution corpuscular multi-beam microscope, without the corpuscular multi-beam microscope having to be switched or the sample having to be moved using a movement device.

A further embodiment of the disclosure provides for making available a method in order, in a sample, simultaneously to charge electrically chargeable structures and to carry out voltage contrast imaging without a precharge mode using a corpuscular multi-beam microscope. The charging and determining of the voltage contrast are thus effected in a temporally overlapping manner or simultaneously during a process of sweeping over the sample in a scanning manner with the corpuscular multi-beam microscope. In this case, during the process of charging the sample with at least one first corpuscular beam of a first quantity of first corpuscular beams, at least one structure is charged in a spatially resolved manner in a targeted way. In this case, a plurality of selected corpuscular beams each having a low corpuscular current produce an additive total current, a charge and hence voltage difference in the electrically chargeable structure. In this method, the charging is effected by a plurality of selected corpuscular beams from the corpuscular beam grid arrangement simultaneously with the voltage contrast imaging. In one embodiment, this disclosure is effected on electrically connected structures such as semiconductor structures, for example, which extend over a plurality of corpuscular beams from the corpuscular beam grid arrangement.

A further embodiment of the disclosure provides for making available a method in order, in a sample, to charge electrically chargeable structures and to carry out high-resolution voltage contrast imaging using a corpuscular multi-beam microscope, wherein the charging of a selected structure is effected in a targeted manner at at least one first scan position of at least one first corpuscular beam and the voltage contrast imaging is effected in a targeted manner at at least one second scan position of at least one second corpuscular beam, wherein a second scan position differs from a first scan position. In one embodiment of the disclosure, at least one of the first charging corpuscular beams can be identical with at least one of the second voltage-contrast-imaging corpuscular beams.

One embodiment of the disclosure relates to a method mentioned above, further including switching the capacitance of an electrically chargeable structure, for example a semiconductor structure, in the sample with a third quantity of third corpuscular beams of the corpuscular multi-beam microscope, and producing a dynamic change in the voltage contrast during the determination of the voltage contrast.

A further embodiment of the disclosure provides for making available a method wherein, using a first arrangement of corpuscular beams, a first structure is charged with a first quantity of charge and, using a second arrangement of corpuscular beams, a second structure is charged with a second quantity of charge in such a way that both structures have an approximately identical voltage, wherein the first and second structures have different capacitances. In this case, the first and second structures can be adapted to the grid arrangement, or a specific, predefined grid arrangement can be provided for the voltage contrast imaging of the first and second structures.

A further embodiment of the disclosure provides a high-resolution corpuscular multi-beam microscope for voltage contrast imaging for a specific electrically chargeable structure, for example a semiconductor structure, wherein the corpuscular beam grid arrangement is adapted to the electrically chargeable structure, for example the semiconductor structure. For this purpose, by way of example, the predefined aperture plate is embodied for producing a spatially adapted corpuscular beam grid arrangement, wherein the corpuscular beam grid arrangement is adapted to the electrically chargeable structure for targeted, simultaneous charging and voltage contrast imaging. For this purpose, the predefined aperture plate has at least one first aperture opening for the charging of a structure, and at least one second aperture opening for the high-resolution voltage contrast imaging of the sample.

One embodiment relates to a corpuscular multi-beam microscope for voltage contrast imaging on a sample, for example semiconductor sample, including at least one first, predefined aperture plate for producing a multiplicity of corpuscular beams arranged in a grid arrangement, wherein the predefined aperture plate is configured for producing at least one first corpuscular beam for cumulatively charging the electrically chargeable structure and at least one second corpuscular beam for voltage contrast imaging on the electrically chargeable structure, and the at least one first corpuscular beam differs from the at least one second corpuscular beam in the image plane of the corpuscular multi-beam microscope, in which image plane the sample is arranged, in at least one property, wherein the at least one property includes beam current, beam spacing, beam focus or beam shape. For this purpose, a corpuscular multi-beam microscope includes at least one predefined aperture plate having different openings or different focusings by way of fine focus optical units and/or a predefined focus array. For example, the at least one predefined aperture plate can be adapted for the charging and voltage contrast imaging on a sample.

In one embodiment, the aperture plate has apertures having different opening diameter or opening areas in order to produce different corpuscular beam currents of different corpuscular beams. At least one first aperture having a first, larger diameter produces large corpuscular beam currents on the sample for charging a structure at a location of the sample which is conjugate with respect to the at least one first aperture, and at least one second aperture having a second, smaller opening area or diameter produces small corpuscular beam currents for high-resolution voltage contrast imaging on the sample at a location which is conjugate with respect to the at least one second aperture.

A further embodiment of the disclosure provides a high-resolution corpuscular multi-beam microscope for voltage contrast imaging for example for semiconductor structures, wherein the high-resolution corpuscular multi-beam microscope is embodied in such a way that the field regions of individual corpuscular beams of the corpuscular beam grid arrangement overlap in the object plane and a sample is thus irradiated multiply with corpuscular beams in the overlap regions. Consequently, for example a semiconductor structure can be charged at at least one location by at least one first corpuscular beam of the corpuscular beam grid arrangement, and the semiconductor structure can be imaged with voltage contrast at at least the same one location by at least one second corpuscular beam of the corpuscular beam grid arrangement. In one configuration of the embodiment, the first and second corpuscular beams can be fashioned differently, for example using assigned apertures having different opening areas or diameters on the aperture plate for producing the corpuscular beam grid arrangement.

In one embodiment, the predefined aperture plate of the high-resolution corpuscular multi-beam microscope can be embodied as exchangeable.

One embodiment of the disclosure relates to a method mentioned above wherein a specific semiconductor structure is configured for voltage contrast imaging with the grid arrangement of a corpuscular beam microscope. A specific semiconductor structure is designed such that charging and voltage contrast imaging are effected in a targeted manner and simultaneously by a plurality of the corpuscular beams from the corpuscular beam grid arrangement.

A further embodiment of the disclosure provides a semiconductor structure for the detection of a small lateral inaccuracy in the layer construction of a semiconductor structure, which leads to a voltage contrast change and, using a corpuscular beam grid arrangement, is both charged and accessible to high-resolution voltage contrast imaging in parallel.

### BRIEF DESCRIPTION OF THE DRAWINGS

The disclosure will be explained in greater detail below with reference to the drawings, in which:

FIG. 1A shows a corpuscular multi-beam microscope on the basis of the example of an MSEM

FIG. 1B schematically shows the beam path of the primary electrons in a corpuscular multi-beam microscope on the basis of the example of an MSEM;

FIG. 1C schematically shows the beam path of the secondary electrons in a corpuscular multi-beam microscope on the basis of the example of an MSEM;

FIG. 2A schematically shows a simplified sectional view in the x-z-direction through a semiconductor;

FIG. 2B schematically shows a simplified sectional view in the x-y-direction through a layer of a semiconductor;

FIG. 3 shows a first exemplary embodiment of charging and voltage contrast imaging on the basis of the example of a typical semiconductor structure;

FIG. 4 shows a section exemplary embodiment with dynamic voltage contrast imaging on the basis of the example of a typical semiconductor structure;

FIG. 5A shows an aperture plate with spatial adaptation of the arrangement of the apertures to a semiconductor structure;

FIG. 5B shows an aperture plate in sectional view with apertures of different sizes;

FIG. 5C shows an aperture plate with a multiplicity of aperture openings for the charging of a semiconductor sample;

FIG. 6 shows an aperture plate with different apertures and different spaces of individual corpuscular beams;

FIG. 7 shows an aperture plate with different apertures and different focal positions of individual corpuscular beams; and

FIG. 8 shows a test structure designed for determining the overlay accuracy of the layer construction of a semiconductor structure with an MSEM.

### DESCRIPTION OF EXEMPLARY EMBODIMENTS

Voltage contrast images are generated by a structure that can take up charge being charged and then observed by observation using a corpuscular beam microscope which employs charged particles. In this case, a primary corpuscular beam is scanned or swept in scanning fashion over a sample to be examined, and reflected corpuscular particles or secondary emissions such as secondary electrons or photons are detected.

Semiconductor structures that can take up charge are typically metals such as the metallic compounds in integrated circuits, but also doped regions in silicon, such as, for example, in photosensitive semiconductor cells or memory cells. In this case, the capacitance of the semiconductor structures can be between a few electrons and a few 100 000 electrons.

Depending on the introduced quantity of charge Q and capacitance C, a potential or voltage difference dV=Q/C forms between the chargeable semiconductor structure and surroundings, and firstly influences the charged particles of the corpuscular beam microscope either attractively or repulsively. Secondly, the charge Q or voltage difference dV also affects the number and energy of the secondary electrons. Overall, therefore, the voltage difference or charging of semiconductor structures influences the imaging with the corpuscular beam microscope. As a result, an altered image contrast in the form of regions appearing bright and regions appearing dark is obtained depending on the charging or voltage difference dV of the semiconductor structure, which is why this is also referred to as voltage contrast imaging. Since the material composition is known for semiconductor structures, the charge state of the semiconductor structure observed can be deduced from the image contrast or the differences in brightness of such voltage contrast images. According to the disclosure, an advantageous method for voltage contrast imaging is effected with a corpuscular multi-beam microscope, or a corpuscular beam microscope having a multiplicity of corpuscular beams.

The minimum lateral structure sizes (CD) of semiconductor structures are currently approximately 5 nm, and it should be expected that the minimum structure sizes will continue to shrink and in a few years will be less than 3 nm, less than 2 nm or even less. A resolution of this order of magnitude of a few nm is possible only with low corpuscular currents.

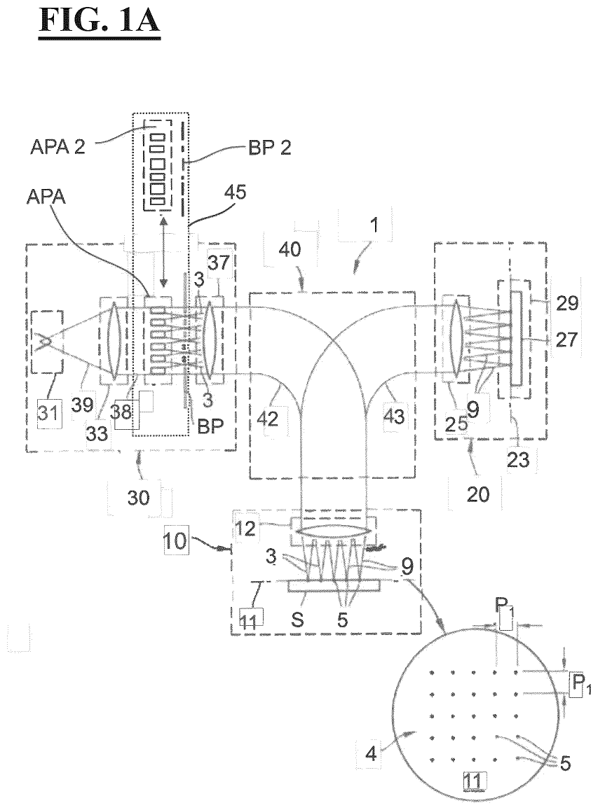

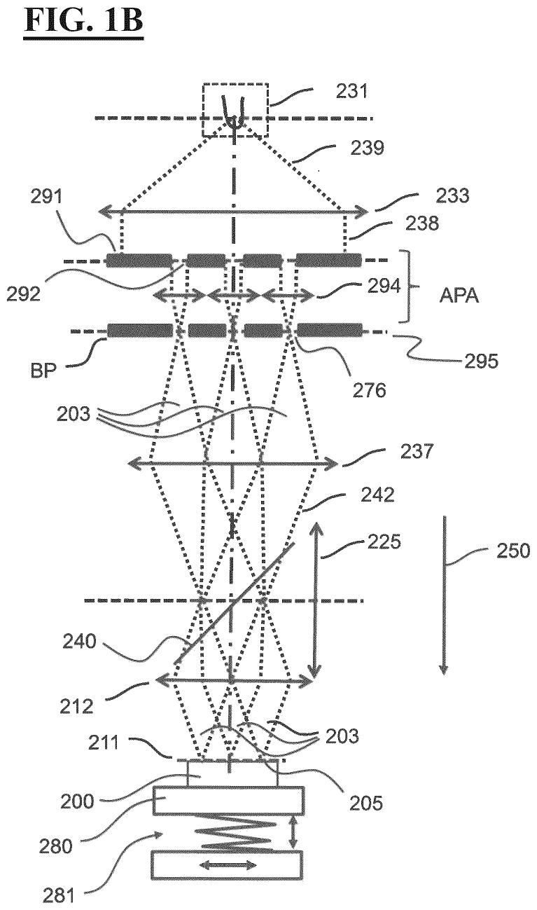

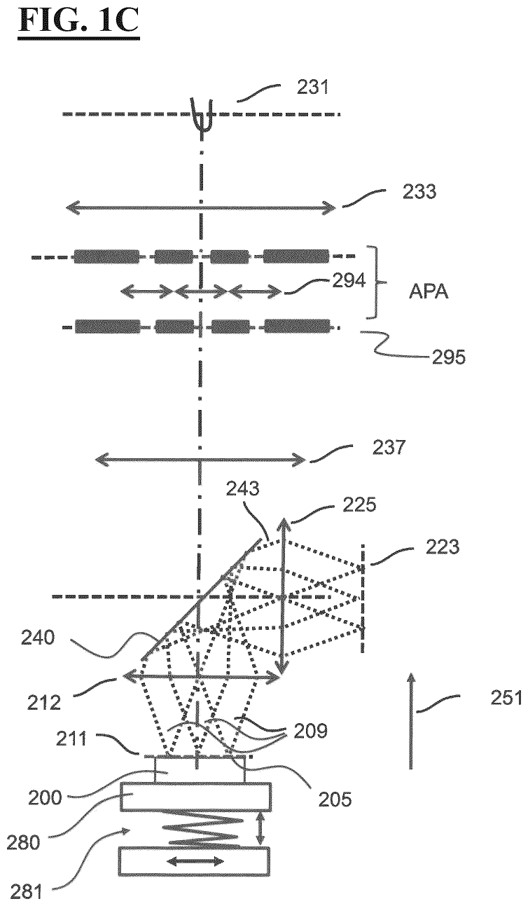

One example of a corpuscular beam microscope having a multiplicity of corpuscular beams with electrons as corpuscular particles is also referred to as “Multi-Beam Scanning Electron Microscope”, abbreviated to MSEM. The functioning of an MSEM will be explained with reference to FIGS. 1A to 1C. FIG. 1A schematically shows the set-up and the function of an MSEM. An MSEM 1 consists of a first object unit 10 having an objective lens 12 and a deflection unit (not illustrated in the figures), by which the electron beams of the MSEM 1 in an object plane 11 can be deflected perpendicularly to the propagation direction of the electron beams in order to scan a field region in the object plane 11 with each electron beam. A sample surface of a sample S can be arranged in the object plane 11 using a positioning unit (not illustrated). In this case, a multiplicity of primary electron beams 3 are focused by the objective lens 12 and a multiplicity of electron beam focal points 5 are produced in an electron multi-bean grid arrangement, grid arrangement 4 for short, in the object plane 11. The multiplicity of secondary electron beams 9, which are taken up and collimated by the objective lens 12, are then directed on the beam paths 43 in the direction of the detection unit 20 via the beam splitter 40. The detection unit 20 includes a projection lens or projection lens system 25, which produces a multiplicity of focal points in an image plane 23 from the multiplicity of secondary electron beams 9. In the image plane, a spatially resolving detector 27 is arranged in a volume 29, and can detect secondary electrons from respectively each electron beam 9 separately.

The multiplicity of primary electron beams 3 are generated by the electron multi-beam generating device 30 having an electron beam source 31, a collimation lens 33, a downstream aperture plate arrangement APA and an objective or field lens 37. Optionally, a multi-beam stop (“blanking plate”) BP is additionally arranged behind the aperture plate arrangement APA. The field lens 37 and the objective lens 12 together form an image of the multiplicity of primary electron beams 3 that pass through the openings in the optional multi-beam stop BP, and thus together form the electron beam focal points or scan points 5 in the image plane 11, wherein the grid arrangement 4 of the electron beam focal points 5 is determined by the design of the aperture plate APA and the optional multi-beam stop (“blanking plate”) BP.

In one embodiment, the predefined aperture plate APA of the high-resolution corpuscular multi-beam microscope together with an optional, assigned multi-beam stop BP can be exchanged. By way of example, provision can be made of a mechanical receptacle 45 in an MSEM, which can receive at least one further, exchangeable aperture plate APA2 and optionally a second BP2. A first aperture plate can for example be one of the specially adapted aperture plates explained below, and a further aperture plate can for example be embodied for smaller corpuscular beam spacings than 10 μm or 12 μm at image plane 11, and for example be designed for smaller corpuscular beam spacings of approximately 5 μm at image plane 11 for voltage contrast imaging on CMOS sensors having pixel sizes of approximately 5 μm, for example. Typical particulate beam spacings at image plane 11 are in the range of 5 μm-15 μm, and embodiments with particulate beam spacings of 100 μm or up to 200 μm are possible.

Between field lens 37 and objective lens 12, the multiplicity of primary electron beams 3 pass through a beam splitter 40 on the beam path 42.

For illustration purposes, FIG. 1A illustrates an electron multi-beam grid arrangement 4 having 25 individual beam focal points 5 in a square regular grid having spacings P1=10 μm. In practice, larger numbers, for example 10×10, 20×20, 100×100 or more individual beam focal points 5, are possible and other grid arrangements 4, for example hexagonal grids, are known, wherein the spacings P1 of the individual beam focal points 5 in the image plane 23 can be in a range of 1 μm to 200 μm.

FIG. 1B schematically elucidates the beam path of the primary electrons in an MSEM, for example the multi-beam generating device. The general beam direction 250 of the primary electrons is identified by an arrow. The electron beam source 231 generates a divergent electron beam 239, which is focused by the collimation lens 233 to form the electron beam 238. The parallel electron beam 238 illuminates the aperture plate arrangement APA. The aperture plate arrangement APA consists of at least one aperture plate 291 having a multiplicity of aperture openings 292 arranged in a grid arrangement, through which a multiplicity of electron beam bundles 203 pass. In the present description, each electron beam bundle 203 passing through an aperture opening 292 is referred to as electron beam or corpuscular beam for simplification. The aperture plate APA furthermore includes the function of focusing the individual electron beams of the multiplicity of electron beams 3. The focusing can be effected by way of an electrode (not illustrated), for example, which forms an electron-optical microlens behind each aperture opening of the aperture plate arrangement APA. Furthermore, a focusing array including a multiplicity of electron-optical lenses or fine focus optical units can be disposed downstream of the aperture plate arrangement APA. For this purpose, additional pairs of electrodes are arranged behind the aperture plate APA. For simplification, the microlenses of the focusing and of the focusing array are illustrated as a lens array 294. A multiplicity of electron beam focal points 276 are thereby produced in a stop plane 295 disposed downstream of the aperture plate APA, a multi-beam stop BP (“blanking plate”) optionally being arranged in said stop plane. The optional multi-beam stop BP contains a multiplicity of openings which are arranged in a grid arrangement, correspond to the focal points 276 of the multiplicity of electron beams 203 and allow the multiplicity of electron beams 203 to pass. Only three aperture openings 292 and three lenses of the lens array 294 and three electron beams 203 are illustrated schematically. The field lens 237 finally converges the electron beam bundles 203 that diverge downstream of the stop plane 295. Using the field lens 237 and the objective lens 212, the multiplicity of electron beam focal points are imaged into the image plane 211 in a reduced manner, for example, and form there the focal points 205 of the primary electron beams 203 of the MSEM in the grid arrangement 4. The stop plane 295 is imaged into the image plane 211 by the field lens 237 and the objective lens 212, and the focal points 276 are thus conjugate with respect to the focal points 205 in the image plane 211. For simplification, it is also stated that the aperture openings 292 and lenses of the lens array 294 are conjugate or assigned to the focal points of the individual beams.

A sample, for example a semiconductor sample 200, which is accommodated on a sample mount 280, is arranged in the image plane 211. The sample mount 280, such as a wafer chuck, for example, is connected to a positioning unit 281, which can have for example five, six or more degrees of freedom for alignment, positioning and movement of the sample.

A small diameter d_{E} of an individual beam focal point is involved for the desired high resolution in the range of a few nm. The diameter d_{E} of an individual beam focal point 205 can be less than 5 nm to 200 nm. The diameter d_{E} is composed of the diameter of the image of the electron beam source d_{source}, the diffraction error d_{diffraction} and the lens aberrations d_{aberrations} of the objective lens 237 and the objective lens 212:

$${d}_{E} = \sqrt{{d}_{diffraction}^{2} + {d}_{s o u r c e}^{2} + {d}_{a b e rration}^{2}}$$

with the diffraction error

$${d}_{diffraction} = \frac{λ}{2 sin a} = \frac{h}{4 \cdot {m}_{e} \cdot {E}_{k i n} \cdot sin α}$$

The electron beam source 231 is imaged in a reduced manner by way of an imaging scale M<1, such that the reduced source image size d_{source} can be disregarded. The lens aberration d_{aberration} is composed of many individual aberrations such as astigmatism, spherical aberration, coma and chromatic aberration or aberration as a result of dispersion over the energy bandwidth ΔE of the electron beam. Lens aberrations increase with the aperture angle α and are minimized by corresponding design and correction of the electron beam optical unit. By way of example, the spherical aberration increases with the aperture angle α approximately to the third power. The aperture angle α is predefined with the aperture openings 292 of the aperture plate APA and increased with the electron imaging with the field lens 237 and the objective lens 212. In order to keep the aberrations small and to ensure a high resolution, the aperture openings 292 of the aperture plate APA are of correspondingly small design for this purpose. The aperture openings 292 of the electron beam bundles 203 for the high-resolution mode have for example small aperture diameters of between 10-50 μm with spacings of between 30-250 μm, for example an aperture diameter of 20 μm with a spacing of 70 μm. A transmission of 4-10% is thus achieved, which corresponds to a low beam current. Further optimization makes it possible to achieve transmissions of up to 15%, or even up to 20% in the high-resolution mode. Consequently, only relatively small apertures with relatively low transmission of less than 20% and thus relatively low beam currents are suitable for the high-resolution mode.

This therefore results in relatively low radiant intensities for the individual high-resolution electron beams of the MSEM. According to the disclosure, however, very many electron beams, for example 25 or 100 or more electron beams, are provided, and a high additive total current is attained.

The primary electrons of each electron beam (3, 203) interact with the sample and either are backscattered or produce secondary electrons. For simplification, backscattered electrons and secondary electrons are both combined hereinafter under the term secondary electrons. Given otherwise constant beam parameters, the proportion of produced or backscattered secondary electrons depends on the local constitution of the sample, such as the surface topography, the material composition or the local voltage difference dV of the sample. FIG. 1C schematically shows the beam path of the secondary electron beams (9,209). The general beam direction 251 of the secondary electrons emanating from the sample 200 is identified by an arrow 251. A portion of the secondary electrons is taken up and converged by the objective lens (12, 212). Consequently, from the multiplicity of individual beam focal points (5, 205) in the grid arrangement 4, a multiplicity of secondary electron beams (9, 209) in the same grid arrangement 4 are produced, wherein respective radiant intensities of the multiplicity of secondary electron beams (9, 209) allow conclusions to be drawn about the respective local constitution, the material composition and the local voltage difference dV of the sample.

Proceeding from the focal points (5, 205), the secondary electron beams (9, 209) are emitted divergently and are imaged by the electron-optical objective lens (12, 212) and jointly with the projection lens (25, 225) into the detector plane (23, 223). In this case, the secondary electrons are deflected by the beam splitter (40, 240) in the direction of the electron-optical projection lens (25, 225). The illustration in FIGS. 1B and 1C is greatly simplified here; the beam splitter 240 can include a plurality of magnetic fields, for example, which deflect the primary electron beams and the secondary electron beams both towards the right without dispersion in the beam direction, for example, as in FIG. 1A. A detection unit (not illustrated in FIG. 1C) is arranged in the detector plane 223.

Furthermore, using a scanning mechanism (not illustrated), the multiplicity of primary electron beams (3, 203) are moved jointly and in parallel over the sample (S, 200). In this case, the focal points (5, 205) are offset over a distance which corresponds to P1 or is somewhat greater than P1 in order that the field regions swept over by different electron beams slightly overlap. Consequently, the surface of the sample is scanned areally and without any gaps by the multiplicity of electron beams (3, 203). Scanning mechanisms for this purpose are generally known. Together with the deflection of the primary electron beams (3, 203), the secondary electron beams (9, 209) are also directed back. The temporal sequence of the signals detected by the detector 27 is converted into a lateral spatial position in the object plane (11, 211). Consequently, in the simplified example illustrated, a gapless, areal image of a segment of the surface of the sample with an extent of 50×50 μm is produced, which is composed of 5×5 individual images with a respective extent of approximately P1=10 μm.

High-resolution imaging is generally understood to mean imaging in which the diameters d_{E} of an individual beam focal point (5, 205) are less than 30 nm, less than 15 nm, for example less than 5 nm, for example down to 3 nm or 2 nm. The extent of the source points of the secondary electron beams (9, 209) can likewise include extents of a few nm, for example less than 30 nm.

FIG. 1A illustrates as an example an MSEM 1 with 25 individual electron beams 3 in the grid arrangement 4. However, the number of electron beams can be much higher, for example 10×10 electron beams, 10 000 electron beams or more. With the high numbers of individual beams which are arranged in a grid arrangement and together sweep over a semiconductor sample in a joint scanning process, a very high throughput is achieved, i.e. an image of a very large area is captured per unit time. For 100 electron beams, an MSEM 1 achieves approximately a throughput of 3.5 mm²/min. With the larger number of beams, an even higher throughput of, for example, 100 mm²/min or more than 350 mm²/min is achieved.

Hereinafter in the application, MSEM 1 is used as representative of corpuscular multi-beam microscopes and is not intended as limitation to electron beam microscopes in the embodiment of an MSEM. Corpuscular particles can generally be charged particles, such as, for example, electrons, metal ions such as gallium ions or ions of noble gases such as helium or neon, for example. Exemplary embodiments of semiconductor samples are explained hereinafter. However, the disclosure is not restricted to semiconductor samples.

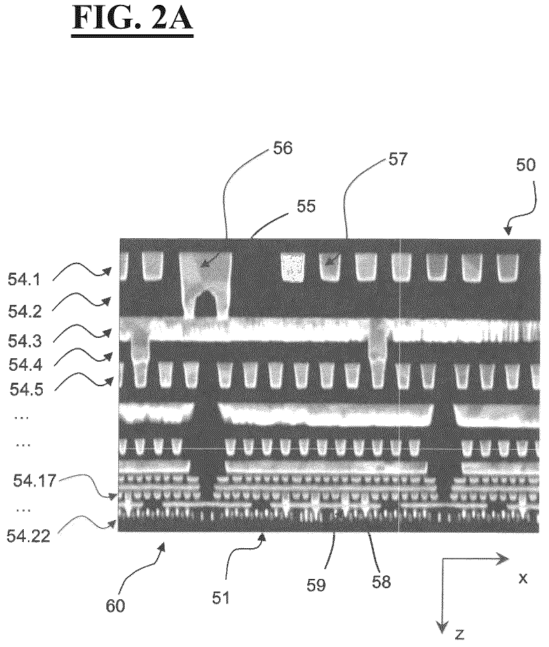

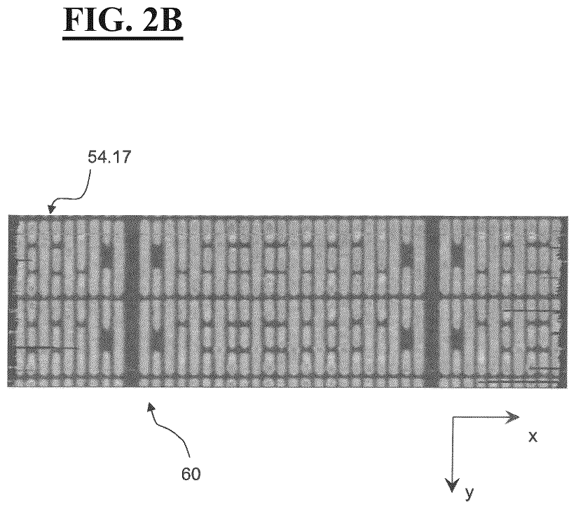

FIGS. 2A and 2B show two typical cross sections through a semiconductor structure. FIG. 2A illustrates a cross section perpendicular to the surface 50 of a semiconductor, wherein the image was generated by a corpuscular beam microscope. The metallic structures appear brighter than the non-conductive structures in the image. The surface 50 of the substrate or wafer delimits the excerpt towards the top. A multiplicity of individual layers 54.1 . . . 54.22 are arranged parallel to the surface 50, each of which layers can be structured. In this case, layers having many conductive structures 54.1, 54.3, . . . alternate with insulation layers 54.2, 54.4 having only few conductive connections or vias. One such conductive connection 55 between one conductive structure 56 in layer 54.1 and the layer 54.3 is illustrated in representative fashion. By contrast, another conductive structure 57 in layer 54.1 has no connection to layer 54.3.

The lateral dimensions of the semiconductor structures and the layer thicknesses of the layers decrease with increasing depth z. The penultimate layer 54.21 directly adjoins a layer 54.22 including, for example, doped structures of the underlying semiconductor material silicon 51. One such doped structure 58 is identified by way of example. A multiplicity of conductive structures is situated therebetween, one structure 59 of which is highlighted by way of example.

The number and selection of the layers should be understood merely as an example; integrated semiconductors can include different numbers of layers and also other layers.

The extents of conductive structures or of structures which can take up charges and are thus accessible to voltage contrast imaging are very varied. The structure 56 is connected to the layer 54.3, wherein the layer 54.3 in this sectional plane is embodied completely as a conductive layer and furthermore has connections to the underlying conductive layer 54.5. This semiconductor structure is therefore very extensive and has a large capacitance C1, which has to be charged with a large quantity of charge Q1 in order to produce a voltage difference dV. The quantity of charge Q1 can be for example a multiplicity of more than a few 10 000 electrons, for example more than 100 000 electrons. By contrast, the doped structure 58 has only a very small extent and has a very small capacitance C2, such that a very small quantity of charge Q2 of a few individual electrons is sufficient for producing a local voltage difference dV. By way of example, if too many electrons are fed to the doped structure 58 and they exceed the capacitance C2 of the doped structure 58, excess electrons flow away and charge adjacent structures such as the structure 59, for example. Consequently, it is no longer possible to determine whether the structure 59 is erroneously connected to the structure 58 or the structure 58 has merely been overcharged with charge carriers.

FIG. 2B shows by way of an example an X-Y section through the layer 54.17. Layer 54.17 contains a multiplicity of conductive connections which vary in their extent and produce connections between structures in layers 54.15 and 54.19.

Conductive structures for example in the lower layers 54.19-54.21 can also be embodied as electrodes of transistors, for example as a gate. Charging of such a gate can for example conductively connect two other semiconductor structures having capacitances C4 and C5 to one another by way of a space charge zone and produce a switchably connected semiconductor structure having a capacitance C6.

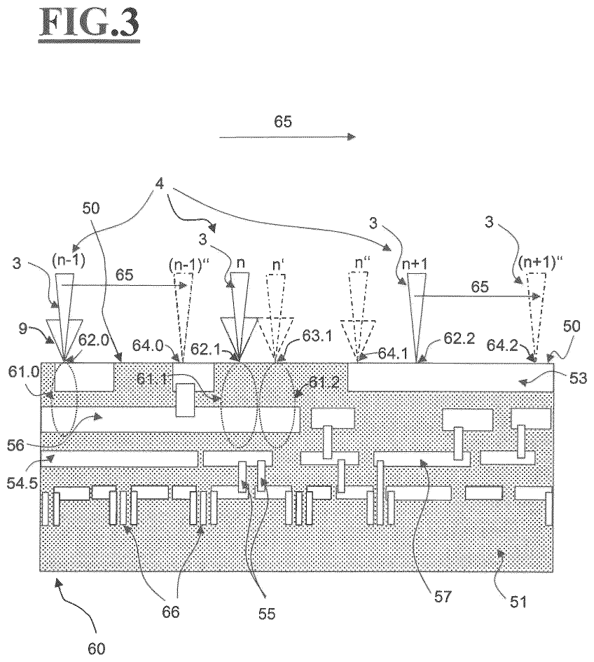

FIG. 3 shows by way of example charging and voltage contrast imaging on a schematically illustrated semiconductor sample 60, wherein charging and imaging are effected on the surface 50 of the semiconductor sample 60, i.e. the surface 50 of the semiconductor sample 60 is arranged in the object plane 11 of the MSEM 1. Near the surface 50 of the substrate 51 composed of silicon, the semiconductor sample 60 contains a multiplicity of layers, of which layer 54.5 is highlighted by way of example. The layers contain conductive structures such as, for example, the structure 57 in the layer 54.5 or gates 66 in the bottommost layer, and also connections or vias 55.

The semiconductor structures are irradiated at the surface 50 by a multiplicity of spaced electron beams 3 in a grid arrangement 4 of the MSEM 1, of which three electron beams 3 designated (n−1), n and (n+1) are illustrated by way of example. In place of the scan or focal points 5 of a primary electron beam 3, a secondary electron beam 9 is emitted from the sample surface 50. The scan positions of the emitted electron beams 9 are largely congruent with the focal points of the primary electron beams 3, but the secondary electron beams 9 have a higher divergence, for example, which is illustrated in a simplified manner by wider beam cones. At each scan position, for example a first scan position 62.0, the (n−1)-th electron beam 3 produces an interaction zone 61.0 with the substrate. The n-th electron beam correspondingly produces an interaction zone 61.1, and an interaction zone 61.2 in the case of a deflection during scanning at a later point in time. In this case, depending on the material and landing energy of the corpuscular beams, the interaction zones 61.0, 61.1 or 61.2 can have an extent of a few 10 nm both perpendicular to the beam direction and in the beam direction. According to the extent of the interaction zone, the irradiation can result in charging of the conductive structures which overlap the interaction zone. Consequently, by way of example, conductive structure 56 is charged both by the (n−1)-th electron beam and by the n-th beam at scan positions 62.0, 62.1 and 63.1 with the interaction zones 61.0, 61.1 and 61.2 and at further scan positions (not depicted). In the example non-conductive material, for example silicon, is situated at the substrate surface 50 of the scan position 62.1. Only a small number of n-th secondary electrons 9 are excited by the primary n-th electron beam 3, and the non-conductive structure appears dark in an image. On the other hand, at the scan position 62.2 of the n+1-th electron beam there is a conductive structure which, upon irradiation with the n+1-th electron beam, emits a multiplicity of n+1-th secondary electrons 9 and appears as a bright region in images such as FIGS. 2A and 2B, for example.

Together with the other electron beams n−1, n+1, the n-th electron beam is guided across the substrate surface 50 along the scanning direction 65 by the scanning unit of the MSEM 1 and in the process passes through a multiplicity of scan positions or focal points (5), for example the second scan position 63.1 and the third scan position 64.1 of the respective n-th electron beam. Besides the electron beam n−1, n, and n+1 illustrated by way of example, a multiplicity of further electron beams (not illustrated) are guided across the substrate surface 50 in the grid arrangement of the MSEM. Overall, a large segment of the semiconductor sample is swept over areally in the process. The primary and secondary electron beam bundles of the n-th electron beam and by way of example individual secondary electron beam bundles are depicted here by dashed lines and identified by reference signs n′ and n″.

In one embodiment, in a semiconductor sample 60 semiconductor structures are precharged in a first step and then voltage contrast imaging is carried out in a second step. In this case, the precharging is effected in the high-resolution corpuscular multi-beam microscope in a first scanning process. The additive total current formed from the sum of the plurality of corpuscular beams, for example 5×5 or 10×10 electron beams, each having a low corpuscular current, brings about a charge and hence voltage difference in the semiconductor structure. The total charge current corresponds to the cumulative sum of the small individual currents of the high-resolution individual beams 3 and thus amounts for example to 25 times or 100 times or more in relation to an individual electron beam. In comparison with an individual high-resolution electron beam of an SEM, the cumulative irradiation of the semiconductor sample 60 by a multiplicity of individual high-resolution electron beams 3 results in the semiconductor sample 60 being charged overall at least 25 times, 100 times or more in comparison with charging by an individual beam with the same beam current and the same residence times at a location on the sample. In the second step, the voltage contrast imaging is effected with a second scanning process using the high-resolution corpuscular multi-beam microscope, without the corpuscular multi-beam microscope having to be switched or the sample having to be moved using a movement device.

With the low individual currents of the multi-beam arrangement 4, therefore, in each case high-resolution voltage contrast imaging with resolutions in the range of a few nm, for example lower than 30 nm, 10 nm or 5 nm, is ensured, and moreover resolutions of 3 nm or 2 nm are possible.

It is thus possible, using of a high-resolution corpuscular multi-beam microscope having low corpuscular currents of individual corpuscular beams 3 of the corpuscular beam grid arrangement 4, in a semiconductor sample 60, in a first step to charge semiconductor structures and in a second step to carry out high-resolution voltage contrast imaging with a lateral resolution in the range of a few nm. In this method for voltage contrast imaging on a semiconductor sample, with a corpuscular multi-beam microscope with a multiplicity of individual corpuscular beams in a grid arrangement, a semiconductor sample having at least one semiconductor structure is swept over in a scanning manner by the multiplicity of individual corpuscular beams. In the process, the semiconductor sample is charged with a first quantity of first corpuscular beams of the corpuscular multi-beam microscope, and a voltage contrast is determined at the at least one semiconductor structure of the semiconductor sample with a second quantity of second corpuscular beams of the corpuscular multi-beam microscope. In this case, at least one first corpuscular beam of the first quantity of first corpuscular beams for charging the sample may not be contained in the second quantity of the second corpuscular beams for imaging the sample or at least one second corpuscular beam of the second quantity of second corpuscular beams may not be contained in the first quantity of the first corpuscular beams.

In a further exemplary embodiment, the charging is effected by a multiplicity of selected individual electron beams with a high spatial resolution. This is illustrated schematically on the basis of two further examples with reference to FIG. 3. For example, in this example, the first step of charging and the second step of voltage contrast imaging can be effected in a temporally overlapping manner or can even be effected completely in parallel during a process of sweeping over a semiconductor sample in a scanning manner.

In this schematic example, the semiconductor structure 53 below the third scan position 64.1 of the n-th electron beam extends to below a first scan position 62.2 of a further, adjacent, n+1-th electron beam of the grid arrangement 4 of the multiplicity of electron beams 3 of the MSEM 1. Before the n-th electron beam reaches the scan position 64.1, the semiconductor structure 53 below the irradiation point 64.1 is charged with the n+1-th electron beam. During the entire scanning process of the n+1-th electron beam, the semiconductor structure 53 experiences targeted, spatially resolved charging, for example at the scan positions 62.2 or 64.2, wherein even further electron beams (not illustrated) can contribute to the charging of the semiconductor structure 53. Consequently, a relatively large quantity of charge is attained, and a semiconductor structure 53 can have a voltage difference dV which enables a contrast change during the imaging at scan position 64.1. The secondary electrons emitted at scan position 64.1, as a result of the accumulated charging, can for example be lower than the secondary electrons emitted at scan position 62.2 as a result of excitation for the first time with the n+1-th electron beam. Charging with a corpuscular beam can thus be effected at at least one first scan position and determining the voltage contrast with a corpuscular beam can be effected at at least one second scan position, which differs from the first scan position.

The simultaneous voltage contrast imaging and charging will be explained on the basis of a further example. At the scan positions 62.1 and 63.1, the n-th primary electron beam excites only a small number of secondary electrons in the insulating material silicon and the insulating structure exhibits no or at most a small change as a result of possible charging of adjoining conductive structures. However, the n-th electron beam, with its interaction zones 61.1 or 61.2 below the scan position 62.1 and 63.1, respectively, contributes in each case to spatially resolved, local charging of the semiconductor structure 56. Likewise, in this exemplary example, the adjacent (n−1)-th electron beam contributes to the charging of the structure 56. Before the (n−1)-th electron beam reaches the scan point 64.0, the connected semiconductor structure 56 thus experiences cumulative charging and hence a voltage difference dV. At the scan point 64.0, on account of the charging and voltage difference dV at the semiconductor structure 56, the (n−1)-th electron beam can excite only a smaller number of secondary electrons 9 and a darker image point occurs.

As a result of the cumulative charging for example of the semiconductor structure 53 or 56 in a semiconductor sample 60 as a result of simultaneous irradiation with a selected multiplicity of at least one first corpuscular beam 3 from a corpuscular multi-beam grid arrangement 4, it is therefore possible to alter the voltage contrast of individual semiconductor structures in a targeted manner during the imaging. The number of the at least one first corpuscular beam 3 of the corpuscular multi-beam microscope 1 can be, for example, greater than or equal to two, such that an additive total current formed from the sum of the at least two first corpuscular beams each having a low corpuscular current produces the charging and hence voltage different in the semiconductor structure 53 or 56. The corpuscular current of a second corpuscular beam for determining the voltage contrast at the semiconductor sample 60 is thus lower than the total corpuscular current—introduced into the semiconductor sample—of the at least one first corpuscular beam for charging the semiconductor sample 60. As shown in the example with the (n−1)-th corpuscular beam, a second corpuscular beam for voltage contrast imaging at a later scan position 64.0 can be identical with a first corpuscular beam at a first, earlier scan position 62.0. In this case, the corpuscular current of a second corpuscular beam for determining the voltage contrast at the semiconductor sample 60 is, for example, lower than the additive total current of the first quantity of first corpuscular beams, such that the accumulated electrical charging of the semiconductor structure 60 remains substantially unchanged as a result of the corpuscular current of the second corpuscular beam. The corpuscular beam microscope can remain unchanged, for example, for charging and determining the voltage contrast, and the individual corpuscular currents of the first and second corpuscular beams can be unchanged and they can be the same.

In this case, the schematic embodiment according to FIG. 3 shows a small excerpt from the corpuscular beam grid arrangement 4 and semiconductor sample 60, and it should be understood that semiconductor structures 53 and 56 can generally be charged locally and in a spatially resolved manner by further individual corpuscular beams (not illustrated). Address lines or read-out lines, for example, can extend over large regions, for example over a plurality of mm in a semiconductor sample 60, and can be charged by a multiplicity, for example 5 or 10 or more, of individual electron beams 3 each having a low individual radiation current. It is therefore possible, in a semiconductor sample 60, simultaneously to charge semiconductor structures and to carry out voltage contrast imaging without a precharge mode using a corpuscular multi-beam microscope. In this case, at least one first corpuscular beam of the grid arrangement 4 at at least one first scan position 62.0, 62.2 and optionally an at least second corpuscular beam of the grid arrangement 4 at at least one second, spaced apart scan position 63.1 bring about charging and hence a voltage difference in the semiconductor structure, wherein at at least one third scan position 64.0, 64.1 spaced apart from the first scan position, the voltage difference dV in the semiconductor structure is detected as a voltage contrast change at the third scan point 64.0, 64.1. In this case, this voltage contrast imaging is effected at at least one electrically connected semiconductor structure 53, 56 which extends over at least two adjacent corpuscular beams 3 from the corpuscular beam grid arrangement 4. In one specific embodiment, the scan regions or field regions of individual corpuscular beams can overlap, such that the first scan point of a first corpuscular beam overlaps the second scan point of a second corpuscular beam.

The multiplicity of corpuscular beams make it possible to charge semiconductor structures having different extents and different capacitances with different charges, such that both a large, extensive semiconductor structure having a large capacitance and a small, limited semiconductor structure having a low capacitance exhibit approximately the same voltage dV. A large, extensive semiconductor structure having a larger capacitance of Ck is charged by a larger number K of individual corpuscular beams 3 with a larger quantity of charge, whereas a smaller, more limited semiconductor structure having a capacitance C1, which extends only over a few or one field region of one corpuscular beam 3, is charged only by a smaller number L of individual corpuscular beams or a single corpuscular beam with a smaller quantity of charge. In this case, a similar voltage difference dV is attained in the two semiconductor structures if L/K corresponds approximately to the ratio Cl/Ck.

In this way, using targeted, cumulative charging of individual semiconductor structures, the underlying structure of the semiconductor sample 60 can be inferred and defects in a semiconductor structure of a semiconductor sample 60 can be deduced for example from obtained images that deviate from expected images.

In this regard, for example, it is possible to check whether two spaced apart line segments in an integrated semiconductor are electrically conductively connected or are perforated or electrically insulated relative to one another. For this purpose, by way of example, the charge is introduced at the first of the two line segments, and the voltage contrast is measured at the other, second line segment of the semiconductor structure. Consequently, on the one hand, it is possible to check whether semiconductor structures which should be electrically conductively connected are actually electrically conductively connected and for example are not interrupted and thereby have a lower capacitance than a target capacitance of this structure. The voltage contrast at such an interrupted structure then deviates from an expected voltage contrast and is higher, for example. On the other hand, it is possible to check whether two semiconductor structures which should not be electrically connected for example are erroneously connected by a short circuit and thereby have a greater capacitance than the target capacitance of this structure. The voltage contrast at such a connected structure then deviates from an expected voltage contrast and is lower, for example.

As a result of the simultaneous charging and voltage contrast imaging, the time segment between charging and voltage contrast imaging is reduced. Consequently, the natural loss of charge in semiconductor samples, for example as a result of leakage or tunnelling currents, is reduced and charges and thus voltages do not decrease, with the result that for example large voltages from small capacitances from small semiconductor structures can be reliably measured.

In a further embodiment, the voltage contrast imaging is effected at semiconductor structures connected to a large capacitance, such as earth, for example. Charging and imaging are then effected at the same semiconductor structure, wherein the fact of whether the semiconductor structure is connected to the large capacitance can be determined from the voltage contrast. In this case, the voltage is low on account of the electrically conductive connection to the large capacitance. In the case of an interruption, the introduced charge cannot flow away, and the voltage is higher, and the image contrast of the semiconductor structure changes. By way of example, the image contrast decreases.

In a further embodiment, quantitative voltage contrast imaging is carried out. This involves determining the capacitance of a so-called “floating” semiconductor structure, which has no connection to a reference potential. Depending on the capacitance of a “floating” semiconductor structure, a specific voltage difference is established upon targeted charging with a specific charge. Said voltage difference is simultaneously produced with a multiplicity of corpuscular beams and determined from the image contrast by way of the high-resolution voltage contrast imaging, wherein the charging and thus the image contrast can vary continuously with the irradiation time. Deviations from desired capacitances of the “floating” semiconductor structures can be detected in this way.

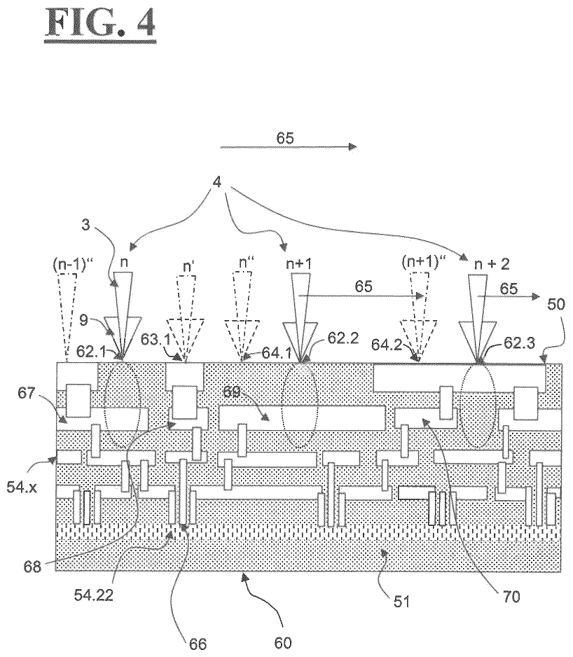

One embodiment of dynamic voltage contrast imaging will be described with reference to FIG. 4. A ramified semiconductor structure 67 having a large capacitance C can be charged by a multiplicity of electron beams 3 having low beam currents during the scan of the multiplicity of electron beams 3 over the substrate surface 50. In the example, in a simplified illustration, these are the (n−1)-th and n-th electron beams. The additive sum of the individual low beam currents of the multiplicity of individual electron beams 3 produces sufficient charging to produce voltage differences of dV which produce a sufficient contrast change in the voltage contrast imaging of the semiconductor structure 67. In this case, the low beam currents also enable high-resolution imaging. In the example in FIG. 4, a further semiconductor structure 68, which is conductively connected to a gate 66, is charged at least at scan position 63.1 of the n-th electron beam. As a result of the charging of the gate, a space charge zone is produced in the doped structure, a so-called fin, in layer 54.22. This produces a connection between the semiconductor structure 67 and a semiconductor structure 69 in an adjacent region lying outside the field region swept over by the electron beam which sweeps over the semiconductor structure 67. Using such switching operations, the introduced charges in semiconductor structures 67 and 69 can compensate for one another, and using further switching operations it is possible to effect compensation with further semiconductor structures, for example with a more distant semiconductor structure 70. In the voltage contrast imaging, for example during the imaging of the structure 67 below the n−1-th electron beam the voltage contrast changes abruptly if the n-th electron beam passes over the scan position 63.1 lying above the semiconductor structure 68 and the charge from semiconductor structure 67 can thus flow away to the semiconductor structure 69. Dynamic voltage contrast imaging in which the image contrast of individual semiconductor structures changes abruptly is effected in this way. During dynamic voltage contrast imaging, by way of targeted, local charging and targeted, local excitation of switching processes that result in a temporally abrupt change in the capacitance and thus charging of semiconductor structures, an abrupt, dynamic contrast change takes place at individual semiconductor structures. By way of example, a first electron beam, while sweeping over a field region, can scan a semiconductor structure multiply in an imaging manner, while a further, third electron beam triggers the switching process and changes, for example doubles, the capacitance of the semiconductor structure, and in the process reduces, for example halves, the voltage. During the process of sweeping over a field region of the semiconductor structure with the first electron beam, the image contrast of this semiconductor structure then changes abruptly by a relatively large absolute value; by way of example, the image contrast doubles as a result of the halving of the voltage. In contrast thereto, during conventional voltage contrast imaging, the voltage contrast changes slowly and continuously as a result of continuously increasing charging.

In one exemplary embodiment of dynamic voltage contrast imaging, voltage contrast imaging or dynamic voltage contrast imaging using the MSEM 1 is also repeated a number of times, for example. In this way, it is possible to record image series over time. Further pieces of information about the temporal profile or temporal changes of the voltage contrast are thus determined. By way of example, a connection effected during a first scan with the MSEM can be interrupted again by a switching process in a later scan of a later image, such that the voltage contrast changes in a targeted manner over individual image recordings of the image series.

Using dynamic voltage contrast imaging, the underlying structure of the semiconductor sample 60 can be inferred and defects in a semiconductor structure of a semiconductor sample 60 can be deduced for example from the dynamic voltage contrast imaging using an MSEM 1. By way of example, this is done by comparing voltage contrast imaging using an MSEM on a reference sample with a sample to be tested and determining possible defects from the differences with respect to the reference image, or by comparing voltage contrast imaging using an MSEM with a simulation of the measurement on CAD data of the semiconductor sample, or by comparing dynamic voltage contrast imaging with conventional, quasi-static voltage contrast imaging.

In this way, it is thus also possible to carry out a functional test of integrated semiconductor components in a semiconductor sample. In one embodiment, by way of continuous, accumulative charging of a semiconductor structure, the capacitance of the semiconductor structure is ascertained from the voltage contrast profile over time. A small capacitance is charged more rapidly and attains a larger voltage difference more rapidly than a comparatively large capacitance. In a further embodiment, semiconductor structures can be switchable and a switching process can be effected, for example by way of the targeted charging of a gate electrode of a transistor, and at the same time the voltage difference change at the then connected or interrupted semiconductor structures can be observed. Targeted charging of a gate electrode of a source-follower transistor with simultaneous voltage contrast measurement furthermore allows an approximate determination of the characteristic curve of the source-follower transistor.

With certain known single-beam microscopes, for example, the scanning direction is set such that the beam sweeps over two contact pads within a line, said contact pads being conductively connected in a semiconductor structure. As a result, the two contact pads are charged to a greater extent than if the semiconductor structure were oriented in a different direction. This can result in differences in the voltage contrast imaging on account of the orientation of the semiconductor sample or scanning direction. With the MSEM having a multiplicity of electron beams arranged next to one another in a grid arrangement, this dependence on the scanning direction or sample orientation is largely eliminated, such that the voltage contrast imaging is effected largely isotropically, i.e. direction-independently.

With certain known single-beam microscope, for example, a semiconductor sample is swept over in a first image field of approximately 10 μm-20 μm in a first scan, and a further image field in a second scan, wherein the semiconductor sample is moved using a table between the first scan and the second scan. The sample can discharge again in the period of time between the first and second scans, thus resulting in attenuation and hence corruption of the voltage contrast imaging. By way of example, a switching connection for dynamic voltage contrast imaging can be interrupted again. With an MSEM having a multiplicity of electron beams arranged next to one another in a grid arrangement, a much larger image field of 100 μm . . . 200 μm or 500 μm is attained, such that undesired discharge processes over longer periods of time have no influence on the voltage contrast imaging. Discharge processes always occur, for example as a result of thermal effects, leakage or surface currents.

In the case of large conductive semiconductor structures having many contact pads connected by through contacts, stronger charging effects are achieved with an MSEM having many electron beams. With the larger image field of the MSEM of up to a few 100 μm, for example up to 500 μm, a broken contact in a semiconductor structure can be identified rapidly before a charged semiconductor structure can discharge again.

A further embodiment of the disclosure provides a high-resolution corpuscular multi-beam microscope for voltage contrast imaging for electrically chargeable structures, wherein at least one property of at least one first and at least one second corpuscular beam of the corpuscular beam grid arrangement is embodied differently, wherein the at least one property can be beam current, beam spacing, beam diameter, focal position or beam shape, for example. In this case, the at least one property of the corpuscular beam is taken to mean a property of the corpuscular beam in the image or object plane 11, in which the sample having electrically chargeable structures can be arranged.

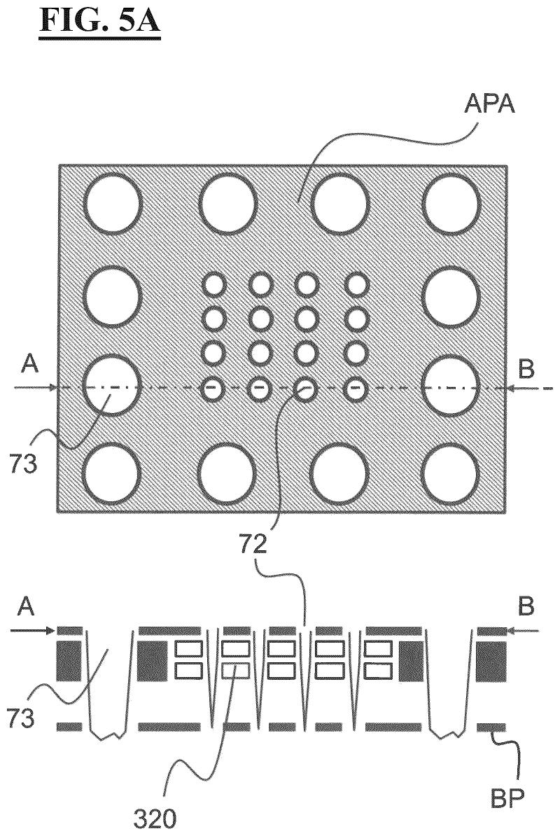

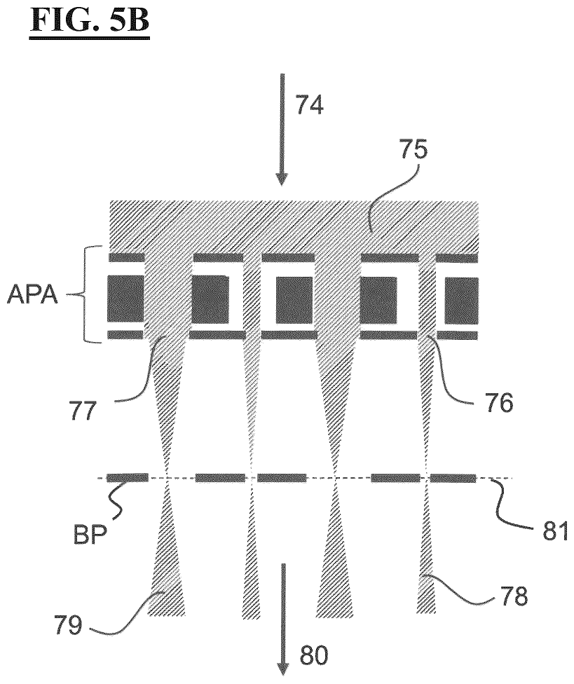

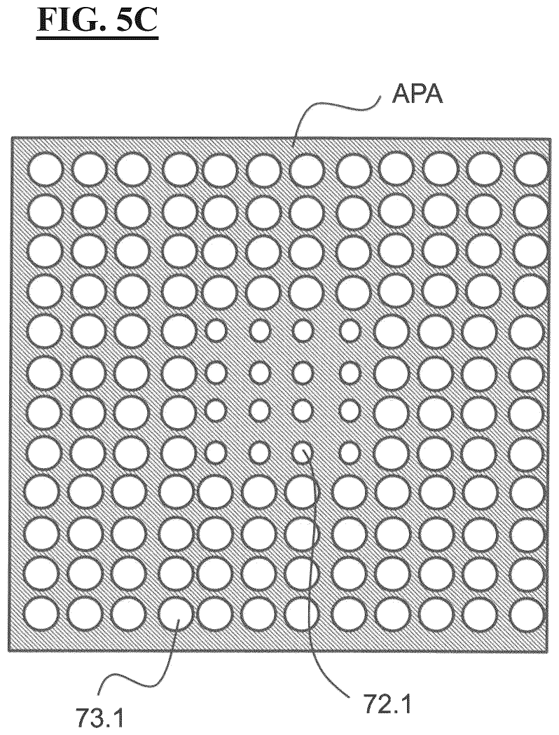

A predefined aperture plate produces a spatially adapted corpuscular beam grid arrangement in the image or object plane 11, which is adapted for simultaneous charging and voltage contrast imaging. In one embodiment, the predefined aperture plate has apertures having different diameters or opening areas for producing different corpuscular beam currents. One example of this embodiment is described in FIG. 5A. In this embodiment, the grid arrangement 4 of the corpuscular multi-beam microscope, for example the MSEM 1, is adapted to the voltage contrast imaging. In this case, a predefined aperture plate APA and an optional multi-beam stop (“blanking plate”) are designed for different individual beam currents and spacings, wherein FIG. 5A shows a plan view of a predefined aperture plate APA.

In the outer region, the aperture plate APA has a number of twelve first, large apertures for first corpuscular beams having large beam currents for charging (one large aperture opening 73 is designated by way of example). In an inner region, the aperture plate APA has sixteen second, small apertures for second corpuscular beams having small beam currents for high-resolution imaging (one small aperture opening 72 is designated by way of example). The distance between respectively first aperture openings having a larger opening area and second aperture openings having smaller opening areas in comparison with the first aperture openings in the corpuscular beam grid arrangement varies in this case. With this embodiment of an aperture plate APA for a corpuscular multi-beam microscope, a semiconductor sample is charged by a first multiplicity of first corpuscular beams having large beam currents, and a high-resolution voltage contrast image is produced using a second multiplicity of second corpuscular beams. A microscope for voltage contrast imaging on a semiconductor sample with a corpuscular multi-beam microscope having a multiplicity of individual corpuscular beams in a grid arrangement is thus provided, wherein the microscope is designed for sweeping over a semiconductor sample having at least one semiconductor structure in a scanning manner using the multiplicity of individual corpuscular beams. In this case, a voltage contrast is determined at the at least one semiconductor structure of the semiconductor sample with a second quantity of second corpuscular beams of the corpuscular multi-beam microscope and the semiconductor sample is charged with a first quantity of first corpuscular beams of the corpuscular multi-beam microscope. In one embodiment, at least one first corpuscular beam of the first quantity of first corpuscular beams is not contained in the second quantity of the second corpuscular beams, or at least one second corpuscular beam of the second quantity of second corpuscular beams is not contained in the first quantity of the first corpuscular beams. The corpuscular beam microscope can remain unchanged for charging and determining the voltage contrast, and the individual corpuscular currents of the first and second corpuscular beams can remain unchanged and be different.

The lower half of FIG. 5A shows a section along the line AB through the aperture plate arrangement APA. The aperture plate arrangement has a microlens array 320 alongside the aperture openings (by way of example 73 and 72), wherein the microlens array 320 in one exemplary embodiment can be embodied only in the beam direction downstream of the small aperture openings 72. With regard to the microlens array, reference is made to the explanations concerning FIG. 1B. The BP (blanking plate) is optionally disposed downstream in the beam direction and allows passage for the focal points of the electron or particulate beams focused by the microlens array 320.

The apertures of the second multiplicity of second particulate beams for the high-resolution mode have for example small aperture diameters of between 10-50 μm with spacings of 30-250 μm. A transmission of 4-10% is thus achieved, which corresponds to a low beam current. Further optimization makes it possible to achieve transmissions of up to 19% in the high-resolution mode. With the large aperture diameters of, for example, 55 μm to 75 μm of the first multiplicity of first particulate beams or high-current beams, a transmission of more than 25%, for instance 30%, or 50%, is achieved. With different apertures, it is possible to set different beam currents between different beams, wherein it is possible to realize different ratios of the beam currents relative to one another in a range of a factor of 2-10. However, the spherical aberration increases with the aperture diameter to approximately the third power with respect to the aperture diameter. Only smaller, second apertures having lower transmission of less than 20% and thus lower beam currents are suitable for the high-resolution mode with resolutions in the range of a few nm or less.

FIG. 5B illustrates a cross section through a predefined aperture plate APA. From the direction 74 of incidence, a focused corpuscular beam 75 (for example electron beam 38 in FIG. 1) is incident on the aperture plate APA having second, small openings 76 and first, large openings 77. Microlenses (see description concerning FIG. 1B) for focusing the first corpuscular beams 79 and second corpuscular beams 78 that pass are additionally arranged in the predefined aperture plate, and focus the corpuscular beams 78 and 79 in the focal plane 81. Furthermore, the multi-beam stop BP is optionally arranged in the focal plane 81. The multiplicity of corpuscular beams in the grid arrangement in accordance with FIG. 5A propagate further in the direction 80. The focal points in the focal plane are then imaged into the object plane 11 of the corpuscular beam microscope by the downstream corpuscular beam optical unit in accordance with FIG. 1.

In the case of an alternating arrangement of large and small openings in the aperture plate APA, as illustrated in FIG. 5B, the microlenses of the focusing array or further fine focus optical units can be embodied identically for first particulate beams 79 and second particulate beams 78, for example with identical diameters. However, it is also possible to design the collimation optical units differently for first particulate beams 79 and second corpuscular beams 78.

As shown in FIG. 5C, an aperture plate arrangement APA of an MSEM, for example, can also have a large number of first (large) aperture openings 73.1, which for example is greater than the number of second (small) aperture openings 72.1 for the high-resolution imaging. This ensures a relatively large additive particulate current for charging a sample for voltage contrast imaging.

The different aperture openings according to the disclosure of the aperture plate arrangement APA can have in addition to the different opening areas for producing a spatially adapted corpuscular beam grid arrangement in the image or object plane 11 further adaptations of the aperture openings of the aperture plate arrangement APA, which make allowance for example for lens aberrations of the downstream imaging system of the corpuscular beams. Such further adaptations of the aperture openings of the aperture plate arrangement APA are described for example in WO2005/024881 (for example FIGS. 14, 15 and 18), which is hereby fully incorporated in the disclosure. What is achieved by said adaptations of the aperture openings of the aperture plate arrangement APA is that the second corpuscular beams having small beam currents for high-resolution imaging in the image or object plane 11 of the MSEM are formed largely identically and each of the first corpuscular beams for voltage contrast imaging attains a largely identical high resolution of, for example, 2 nm during the voltage contrast imaging by virtue of the fact that adapted aperture openings of the aperture plate arrangement APA make allowance for field-dependent lens aberrations such as, for example, astigmatism or image field curvature of the downstream imaging system for each corpuscular beam. The adaptation of the aperture openings of the aperture plate arrangement APA can furthermore include small displacements of the aperture openings in order to compensate for distortion aberrations of the downstream imaging system for each corpuscular beam and to ensure a uniform, equidistant arrangement of individual corpuscular beams in the image plane 11 for voltage contrast imaging.

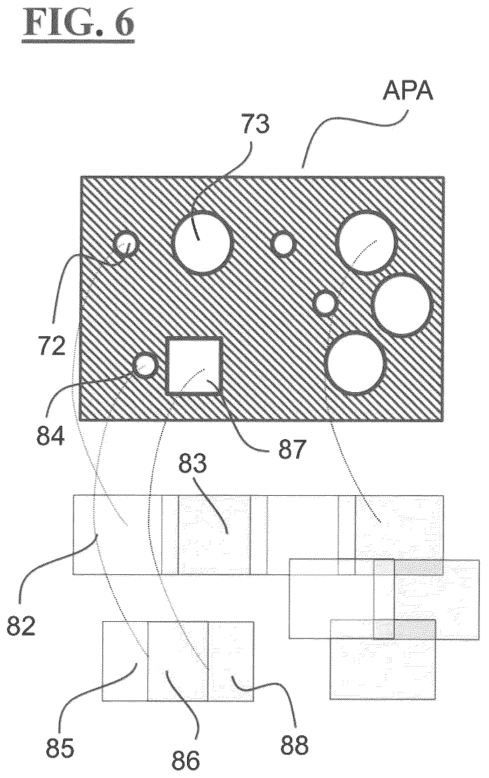

FIG. 6 shows a further grid arrangement 4 on the basis of a predefined aperture plate APA having small apertures and large apertures, with the assigned image field segments which are swept over in each case by the electron beam produced by each aperture during scanning in the object plane and which are covered by the common scan of the multiplicity of corpuscular beams. A small aperture opening 72 shapes a second corpuscular beam to which a second image segment 82 is assigned. A further, large aperture opening 73 shapes a first corpuscular beam to which a first image segment 83 is assigned. The image segments 82 and 83 and also all further image segments which are assigned to the further corpuscular beams of the corpuscular beam grid arrangement are at least partly aerially scanned by the scanning unit of the corpuscular beam microscope.

By way of a predefined aperture plate APA, it is thus possible to image individual second image field segments in the object plane with high resolution with second corpuscular beams and, in other, first image field segments, to charge a semiconductor sample with first corpuscular beams having higher corpuscular currents. For this purpose, the predefined aperture plate has at least one first, larger aperture for charging a semiconductor structure at the conjugate first image field segment of the at least one first larger aperture, and at least one second, smaller aperture for high-resolution voltage contrast imaging on the semiconductor sample at the conjugate second image field segment of the at least one second smaller aperture.

In one embodiment, the corpuscular beam grid arrangement is designed in such a way that the image field segments of different individual corpuscular beams overlap during scanning. As a result of the overlapping of the image field segments, a semiconductor sample is irradiated multiply with corpuscular beams at the overlap locations. One example of an overlap region is highlighted by reference numeral 86 in FIG. 6. A second image segment 85 is assigned to a second, smaller aperture 84, and the first image segment 88 is assigned to a first, larger aperture 87, wherein the two apertures 84 and 87 have a smaller spacing, which is smaller for example than the scan region of the two electron beams that pass through the apertures 84, 87 in the object plane. The assigned image field segments 85 and 88 therefore shape a large overlap region 86. In this case, the overlap region is for example greater than 20% of an image field segment, for example greater than 50% of an image field segment. Before the second corpuscular beam formed by the second aperture 84 reaches the overlap region 86, the latter has already been precharged by the first corpuscular beam formed by the first aperture 87. Consequently, a semiconductor structure can be charged at at least one location by at least one first corpuscular beam of the corpuscular beam grid arrangement, and the semiconductor structure can be imaged at at least the same location by at least one second corpuscular beam of the corpuscular beam grid arrangement at a later scan position with voltage contrast.

As illustrated, in one example, the first and second apertures 72, 84 and 73, 87 besides having different extents and opening areas, can also have different shapes; in this regard, for example, the second, large apertures can also be hexagonal (not illustrated) or rectangular and thus produce different beam cross sections or intensity distributions of the particles or corpuscular particles in the object plane. What can furthermore be achieved as a result is that the focal points of the first corpuscular beams in the image plane of the corpuscular multi-beam microscope for charging an electrically chargeable structure have larger extents than for example the focal points of the second corpuscular beams in the image plane of the corpuscular multi-beam microscope for high-resolution voltage contrast imaging.

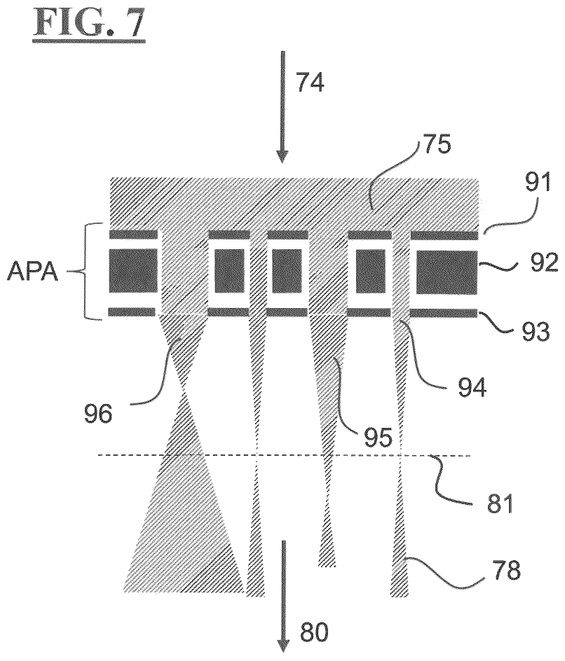

FIG. 7 shows a further configuration of the predefined aperture plate APA. An aperture plate 91 is succeeded by a grid arrangement of different fine focus optical units 92, and a main focusing optical unit 93, consisting of many electron-optical optical lenses, which together focus electron beam bundles 78, 95 and 96 that pass through the aperture plate 91 in each case. In this example, no multi-beam stop BP is arranged downstream of the aperture plate APA, but a multi-beam stop BP having different stop openings can be provided. The fine focus optical units 92 have different focusing effects for each corpuscular beam, such that for example a corpuscular beam 78 for high-resolution imaging is focused in the focal plane 81 by the joint effect of the main focusing optical unit 93 and a fine focus optical unit 92 with a medium focusing effect. In comparison therewith, the fine focus optical unit 92 has a stronger focusing effect for a corpuscular beam 96, such that the corpuscular beam 96 for areal charging with a high current and a large aperture is focused to a focal point upstream of the focal plane 81 and thus leads to areal charging of a semiconductor sample in the object plane of the MSEM 1, said object plane being conjugate with respect to the focal plane 81. A further corpuscular beam 95 for local charging with a high current is focused to a focal point by the main focusing optical unit 93 and the focusing effect of the fine focus optical unit 92 which is weaker than that for the corpuscular beam 78, said focal point being spaced only at a distance downstream of the focal plane 81 and thus likewise leading to areal charging of the semiconductor sample in the object plane of the MSEM 1, said object plane being conjugate with respect to the focal plane 81, wherein the charging by the corpuscular beam 95 is effected with a smaller lateral extent, however, than that effected by the corpuscular beam 96.

As explained above, the—according to the disclosure—different aperture openings of the aperture plate arrangement APA and different focusing effects of the fine focus optical units for producing a spatially adapted corpuscular beam grid arrangement in the image or object plane 11 can have further adaptations of the aperture openings of the aperture plate arrangement APA or focusing effects of the fine focus optical units, which make allowance for example for lens aberrations of the downstream imaging system of the corpuscular beams. Different focusing effects of the fine focus optical units can additionally be included, for example, in order to make allowance for an image field curvature of the downstream imaging system of the corpuscular beams.

Using a corpuscular multi-beam microscope, voltage contrast imaging is possible without the need to provide additional electron beam guns for precharging semiconductor samples or without a corpuscular beam microscope having to be switched from a precharge mode to the high-resolution mode. Using the predefined aperture plate, voltage contrast imaging using a corpuscular multi-beam microscope is possible which is adapted to a specific semiconductor sample. By exchanging aperture plates APA, it is possible to adapt a corpuscular multi-beam microscope 1 to different semiconductor samples 60 without the corpuscular multi-beam microscope 1 having to be replaced. For this purpose, provision can be made of a change unit for changing aperture plates APA in the corpuscular multi-beam microscope (see FIG. 1A).

In an alternative embodiment of the disclosure, a semiconductor sample is disclosed which contains specific semiconductor structures for voltage contrast imaging which are adapted to a corpuscular multi-beam microscope with a predefined aperture plate APA. Said specific semiconductor structures at which voltage contrast images are generated can be either functional semiconductor structures or else semiconductor structures which are introduced into the integrated semiconductors only for the purpose of process monitoring and representative function monitoring of the semiconductor. These semiconductor structures, also called test structures, are also referred to in English as process control monitors (PCM). Said specific semiconductor structures are designed such that charging and voltage contrast imaging are effected in a targeted manner and simultaneously using a plurality of the corpuscular beams from the corpuscular beam grid arrangement.

For this purpose, specific semiconductor structures are configured with spacings and extents which are adapted to predefined corpuscular beam spacings, or the semiconductor structures are designed in such a way that they extend in a ramified fashion in at least one direction such that charging is effected with a multiplicity of at least two individual corpuscular beams. Test structures can furthermore be configured from a plurality of semiconductor structures which form switching elements such as transistors, for example.

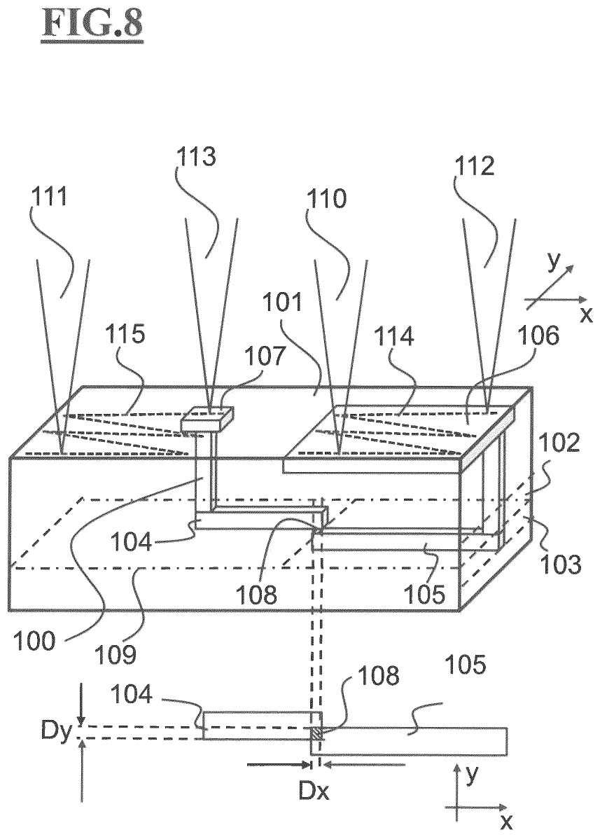

An exemplary embodiment of a semiconductor structure configured for voltage contrast imaging with a corpuscular multi-beam microscope is elucidated in FIG. 8. A semiconductor structure in a semiconductor sample for simultaneous charging and voltage contrast imaging with a corpuscular multi-beam microscope contains near-surface elements adapted to the beam spacing of at least two corpuscular beams of the corpuscular multi-beam microscope. Typical particulate beam spacings are in the range of 5 μm-12 μm; embodiments with particulate beam spacings of 100 μm or up to 200 μm are possible.

FIG. 8 shows a semiconductor structure for detecting a small lateral inaccuracy in the layer construction of a semiconductor structure. Such lateral inaccuracies are also referred to as overlay errors. The desired overlay accuracy or overlay of the semiconductor layers is in the range of a fraction of the minimum structure size or CD (“critical dimension”). For the bottommost layers of an integrated semiconductor, the minimum structure sizes at the present time are approximately 5 nm, and minimum structure sizes of 3 nm or less are foreseeable in the near future. The overlay accuracy between such a layer and an adjacent layer is therefore less than 2 nm, and less than 1 nm in the near future.

In order to measure small overlay accuracies of less than 2 nm, therefore, specific test structures are configured for which a small, lateral inaccuracy of less than 2 nm results in an interruption of a conductive contact.

FIG. 8 shows a specific semiconductor structure 100 which can be used to carry out non-destructive testing of an overlay error of less than 2 nm with voltage contrast imaging with a corpuscular multi-beam microscope 1. For this purpose, a semiconductor structure 100 is configured in such a way that it is charged with a first corpuscular beam via a first, near-surface structure 106. The first corpuscular beam is illustrated in a simplified manner at a first scan position 110 and at a second scan position 112. The first near-surface structure 106 is conductively connected to a structure 105 situated deeper in the semiconductor sample. In the example, the deeper structure 105 is situated in the (1+1)-th layer 103. The first near-surface structure 106 is embodied in large fashion for this purpose, such that a large portion of the first scan path 114 or the image field segment of the first corpuscular beam overlaps the structure 106. The semiconductor structure 100 furthermore has a second, smaller near-surface structure 107. A second corpuscular beam is illustrated in a simplified manner at a first scan position 111 and at a second scan position 113. The second corpuscular beam sweeps over said second, smaller near-surface structure 107 with the second scan path 115 only at the end of the common scan of the two corpuscular beams, namely at the second scan position 113. The second, small near-surface structure 107 is conductively connected to a deeper structure 104 in a layer (hereinafter 1-th layer 102) adjacent to the (1+1)-th layer 103. In this case, the structures 104 and 105 are configured such that they form a contact zone 108 in the overlap region in the interface 109 between the 1-th layer 102 and the (1+1)-th layer 103, with an extent Dx in at least one direction which is smaller than the permissible overlay error in this direction. This is illustrated on the basis of a sectional view in plane 109 in the lower part of FIG. 8. The extent Dx can be less than 2 nm or less than 1 nm, for example. An electrically conductively connected semiconductor structure 100 is formed by way of said contact zone. Using the parallel scanning process, the structure 100 is charged with the first corpuscular beam 110, 112 during the first scan path 114, such that the second corpuscular beam registers a voltage contrast change at the second scan point 113 and a connected structure 100 can thus be deduced. If there is an overlay error greater than Dx in the x-direction between the 1-th layer 102 and (1+1)-th layer 103, such that for example the 1-th layer 102 is displaced in the negative x-direction and/or the (1+1)-th layer 103 is displaced in the positive x-direction, the contact zone is interrupted and the second corpuscular beam cannot register a voltage contrast change at the second scan point 113. A second, mirrored semiconductor structure can be provided for overlay errors in the opposite displacement direction of the two layers 102, 103. Semiconductor structures for overlay errors in the y-direction can be embodied analogously in a manner rotated by 90°, or be embodied as an embodiment of the contact zone 108 with an overlap region Dy in the y-direction, as illustrated in FIG. 8. With such a specific semiconductor structure 100, an overlay area between two layers in an integrated semiconductor can thus be determined non-destructively using voltage contrast imaging with a corpuscular multi-beam microscope. These test structures have overlap regions between two layers of the semiconductor and can form contact zones having extents Dx and/or Dy of the order of magnitude of a fraction of the CD, for example of less than 2 nm or less than 1 nm.

In the application, the MSEM 1 or an electron beam of an electron beam grid arrangement is used as representative of corpuscular multi-beam microscopes and is not intended as limitation to electrons as corpuscular particles or electron beam microscopes in the embodiment of an MSEM. Corpuscular particles can generally be charged particles, such as, for example, electrons, metal ions such as gallium ions or ions of noble gases such as helium or neon, for example.

In the examples, the voltage contrast imaging is explained in a simplified manner for the case in which the image contrast at the semiconductor structure decreases as the voltage increases. Depending on the choice of the position in the so-called “yield curve” of the secondary corpuscular particles, however, it is also possible for the image contrast at the semiconductor structure to increase as the voltage increases. However, the increase in the image contrast as the voltage increases allows voltage contrast imaging according to the disclosure in a totally analogous manner and is encompassed by the exemplary embodiments.

In the examples for example in FIG. 1, an MSEM 1 is illustrated schematically with individual beam splitters or lenses, such as collimation lenses, objective lenses, field lenses, appertaining to beam optics. It goes without saying for a person skilled in the art that this illustration is a simplification and beam splitters or lenses appertaining to beam optics can be formed from a plurality of electromagnetic elements.

A further aspect of voltage contrast imaging in conjunction with simultaneous charging with a corpuscular multi-beam microscope is the increased throughput of a corpuscular multi-beam microscope compared with a single-beam microscope. The number of corpuscular beams is higher by a multiple than in a single-beam microscope such as an SEM, for example 100 times, 1000 times or 10 000 times higher. With the high numbers of individual corpuscular beams which are arranged in a grid arrangement and together sweep over a semiconductor sample in a joint scanning process, a very high throughput is achieved, i.e. a voltage contrast image of a very large area of the semiconductor sample is captured per unit time. With the cumulative charging by a multiplicity of corpuscular beams, the corpuscular multi-beam microscope does not have to be switched, and there is a high resolution of the voltage contrast imaging with a resolution of better than 30 nm or even better than 5 nm and a throughput of more than 3.5 mm²/min. For example with exchangeable or predefined aperture plates or on predefined semiconductor structures, this allows fast process monitoring, such as, for example, the determination of the overlay error in a semiconductor sample.

The illustrations of the semiconductor structures are schematic and greater simplified. However, on the basis of the illustrations and explanations of the examples mentioned above, a person skilled in the art can grasp the underlying concepts and explanations and apply them respectively to real semiconductors and real corpuscular beam microscopes using customary action.

In the exemplary embodiments, the voltage contrast imaging with a corpuscular multi-beam microscope is explained on the basis of the example of semiconductor samples. Generally, the voltage contrast imaging with a corpuscular multi-beam microscope according to the disclosure can be effected on any desired samples which contain electrically chargeable structures. The examples implemented on the semiconductor samples can be applied to any other samples. Such samples can be mineralogical samples, biological samples, or for example microscopic samples produced by 3D printing.

Furthermore, the exemplary embodiments should not be understood as isolated exemplary embodiments, but rather can also be combined in an expedient way by a person skilled in the art; in this regard, for example, the exemplary embodiment in accordance with FIG. 8 can be combined with an exemplary embodiment in accordance with FIG. 1 or FIGS. 5 to 7.

### LIST OF REFERENCE SIGNS

1 Corpuscular multi-beam microscope on the basis of the example of an MSEM
3 Electron beams
4 Electron multi-beam grid arrangement, grid arrangement for short
5 Electron beam focal points
9 Secondary electron beams
10 Object unit
11 Image or object plane
12 Objective lens
20 Detection unit
23 Image plane
25 Projection lens
27 Detector
29 Volume
30 Electron multi-beam generating device
31 Electron beam source
33 Collimation lens or collimation lens system
37 Field lens or field lens system
38 Parallel electron beam
39 Divergent electron beam
40 Beam splitter
42 Beam path from electron multi-beam generating device 30 to object unit 10
43 Beam path from object unit 10 to detection unit 20
45 Mechanical unit for exchange of APA and BP
50 Surface of the substrate or wafer
51 Semiconductor material silicon
53 First semiconductor structure
54.1-22 Multiplicity of individual layers
54.17 Selected layer
54.22 Doped layer
55 Conductive connection or via
56 Semiconductor structure having a large capacitance
57 Conductive structure
58 Doped structure or fin having a small capacitance
59 Semiconductor structure having a medium capacitance
60 Semiconductor sample
61.1, 61.2 Interaction zones
62.1, 62.2, 62.3 First scan position of the n-th, n+1-- and n+2-th electron beams
63.1 Second scan position of the n-th electron beam
64.1, 64.2 Third scan position of the n-th and n+1-th electron beams
65 Scanning direction
66 Gate
67 Ramified semiconductor structure
68 Further semiconductor structure
69 Further semiconductor structure
70 Further semiconductor structure
72 Small aperture opening
73 Large aperture opening
74 Direction of incidence of the incident corpuscular beam
75 Incident focussed corpuscular beam
76 Small opening
77 Large aperture opening
78 Corpuscular beam having a small beam current
79 Corpuscular beam having a large beam current
80 Direction of the individual corpuscular beams of a corpuscular beam grid arrangement
81 Focal plane
82 Image field segment with respect to the aperture 72
83 Image field segment with respect to the aperture 73
84 Further small aperture
85 Image segment with respect to the aperture 84
86 Overlap region
87 Further large aperture
88 Image segment with respect to the aperture 87
91 Aperture plate
92 Fine focus optical units
93 Focusing array
94 Corpuscular beam for high-resolution imaging
95 Corpuscular beam for local charging with high current
96 Corpuscular beam for areal charging with high current
100 Semiconductor structure for measuring overlay errors
101 Surface
102 Layer 1
103 Layer 1+1
104 Structure in layer 1
105 Structure in layer 1+1
106 First near-surface structure
107 Second near-surface structure
108 Contact zone
109 Contact area between layer 1 and layer 1+1
110 First corpuscular beam at first scan position
111 Second corpuscular beam at first scan position
112 First corpuscular beam at second scan position
113 Second corpuscular beam at second scan position
114 First scan path
115 Second scan path
200 Substrate S or sample
203 Primary electron beam bundle
205 Focal points of the individual beam bundles 203 in the image plane 211
209 Secondary electron beam bundles
211 Image plane
212 Electron-optical imaging lens
223 Detector plane
225 Electron-optical imaging lens
231 Electron beam source
233 Electron-optical converging lens
237 Electron-optical imaging lens or field lens
238 Collimated electron beam
239 Divergent electron beam bundle
240 Beam splitter
242 Primary electron beam bundle
276 Electron beam focal points in the openings of the blanking plate BP
280 Substrate receptacle, for example wafer chuck
281 Movement table
291 Aperture plate
292 Aperture openings of the aperture plate
294 Microlens array
295 Focal plane of the microlens array 294
320 Microlens array

What is claimed is:

1. A method of voltage contrast imaging a semiconductor sample, the method comprising:
using a charged particle source of a corpuscular multi-beam microscope to produce a corpuscular beam;
impinging the corpuscular beam onto an aperture plate so that:
i) some of the corpuscular beam is blocked by the adapted aperture plate;
ii) a first portion of the corpuscular beam passes through apertures of a first portion of the aperture plate to produce a first plurality of individual corpuscular beams; and
iii) a second portion of the corpuscular beam passes through apertures of a second portion of the aperture plate to produce a second plurality of individual beams;
simultaneously scanning the first and second pluralities of individual corpuscular beams over a semiconductor sample so that:
i) the first plurality of individual corpuscular beams electrically charges a structure of the semiconductor sample; and
ii) the second plurality of individual corpuscular beams is used to determine a voltage contrast at the electrically chargeable structure of the semiconductor sample,
wherein the first plurality of individual corpuscular beams differs from the second plurality of individual corpuscular beams with respect to at least one member selected from the group consisting of beam current, beam spacing, beam focus and beam shape.

2. The method of claim 1, further comprising exchanging the aperture plate with a different aperture plate.

3. The method of claim 1, wherein the first plurality of individual corpuscular beams comprises at least one first individual corpuscular beam.

4. The method of claim 1, wherein the second plurality of individual corpuscular beams comprises at least one second individual corpuscular beam.

5. The method of claim 1, wherein:
the first plurality of individual corpuscular beams comprises at least two different first individual corpuscular beams;
each of the at least two first individual corpuscular beams comprises a corpuscular current; and
an additive total current comprises a sum of the corpuscular current of the at least two first individual corpuscular currents generates an accumulated electrical charging at the structure of the semiconductor sample to form a voltage difference.

6. The method according to claim 5, wherein:
the second plurality of individual corpuscular beams comprises a second individual corpuscular beam having a corpuscular current that is less than the additive total current so that an accumulated electrical charging of the structure of the semiconductor sample is unchanged.

7. The method of claim 1, wherein:
sweeping the first plurality of individual corpuscular beams to electrically charge the structure of the semiconductor sample is achieved with a first individual corpuscular beam at at least a first scan position; and
simultaneously using the second plurality of individual corpuscular beams to determine a voltage contrast at the electrically chargeable structure of the semiconductor sample at at least one second scan position, which differs from the first scan position.

8. The method according to claim 1, further comprising:
focusing a second individual corpuscular beam of the second plurality of individual corpuscular beams in a focal plane; and
focusing a first individual corpuscular beam of the first plurality of individual corpuscular beams to a focal point upstream of the focal plane.

9. The method according to claim 1, further comprising:
focusing a second individual corpuscular beam of the second plurality of individual corpuscular beams in a focal plane; and
focusing a first individual corpuscular beam of the first plurality of individual corpuscular beams to a focal point downstream of the focal plane.

10. The method of claim 1, wherein the first plurality of individual corpuscular beams differs from the second plurality of individual corpuscular beams with respect to beam current.

11. The method of claim 1, wherein the first plurality of individual corpuscular beams differs from the second plurality of individual corpuscular beams with respect to beam spacing.

12. The method of claim 1, wherein the first plurality of individual corpuscular beams differs from the second plurality of individual corpuscular beams with respect to beam focus.

13. The method of claim 1, wherein the first plurality of individual corpuscular beams differs from the second plurality of individual corpuscular beams with respect to beam shape.

14. The method of claim 1, wherein the apertures of the first portion of the aperture plate have a different size than the apertures of the second portion of the aperture plate.

15. The method of claim 1, wherein the apertures of the first portion of the aperture plate have a different shape than the apertures of the second portion of the aperture plate.

16. A corpuscular multi-beam microscope, comprising:
a charged particle source configured to produce a corpuscular beam;
an aperture plate comprising a first portion comprising a plurality of first apertures and a second portion comprising a plurality of second apertures,
wherein:
the corpuscular multi-beam microscope is configured so that, during use of the corpuscular multi-beam microscope a corpuscular beam generated by the charged particle source impinges on the aperture plate so that:
i) some of the corpuscular beam is blocked by the adapted aperture plate;
ii) a first portion of the corpuscular beam passes through the first apertures to produce a first plurality of individual corpuscular beams; and
iii) a second portion of the corpuscular beam passes through the second apertures to produce a second plurality of individual beams; and
the first plurality of individual corpuscular beams differs from the second plurality of individual corpuscular beams with respect to at least one member selected from the group consisting of beam current, beam spacing, beam focus and beam shape.

17. The corpuscular multi-beam microscope of claim 16, wherein at least one of the following holds:
the first apertures have a different size than the second apertures; and
the first apertures have a different shape than the second apertures.

18. The corpuscular multi-beam microscope of claim 16, wherein the aperture plate is exchangeable.

19. A corpuscular multi-beam microscope, comprising:
a charged particle source configured to produce a corpuscular beam;
an aperture plate comprising a first portion having a plurality of first apertures and a second portion comprising a plurality of second apertures,
wherein:
the corpuscular multi-beam microscope is configured so that, during use of the corpuscular multi-beam microscope a corpuscular beam generated by the charged particle source impinges on the aperture plate so that:
i) some of the corpuscular beam is blocked by the adapted aperture plate;
ii) a first portion of the corpuscular beam passes through the first portion of the aperture plate to produce a first plurality of individual corpuscular beams; and
iii) a second portion of the corpuscular beam passes through the second portion of the aperture plate to produce a second plurality of individual beams; and
at least one of the following holds:
i) the first apertures have a different size than the second apertures; and
ii) the first apertures have a different shape than the second apertures.

20. The corpuscular multi-beam microscope of claim 19, wherein the aperture plate is exchangeable.
